(19) United States
(12) Patent Application Publication
(10) Pub. No.: US 2024/0324354 A1
(43) Pub. Date: Sep. 26, 2024

(54) DISPLAY PANEL

(71) Applicant: Samsung Display Co., Ltd., Yongin-Si (KR)

(72) Inventors: JUCHAN PARK, Yongin-si (KR); SUNHO KIM, Yongin-si (KR); CHUNG SOCK CHOI, Yongin-si (KR); JONGHEE PARK, Yongin-si (KR)

(21) Appl. No.: 18/596,635

(22) Filed: Mar. 6, 2024

(30) Foreign Application Priority Data
Mar. 21, 2023 (KR) 10-2023-0036584

(51) Int. Cl. H10K 59/131; H10K 59/122

(52) U.S. Cl. CPC H10K 59/131; H10K 59/122

(57) ABSTRACT

A display panel is disclosed that includes a light-emitting element including a first electrode, a second electrode, and an intermediate layer, a transistor electrically connected to the light-emitting element, a connection line including a driving connection part connected to the transistor and an emission connection part connected to the second electrode, a first organic layer arranged between the transistor and the connection line, a second organic layer arranged on the first organic layer and between the transistor and the light-emitting element, and a pixel defining layer arranged between the first electrode and the second electrode and having defined therein a first opening overlapping at least a portion of the first electrode and a second opening spaced apart from the first opening, wherein the second electrode includes one end connected to the emission connection part and another end spaced apart from the one end in a cross-sectional view.

### CROSS-REFERENCE TO RELATED APPLICATIONS

This U.S. non-provisional patent application claims priority under 35 U.S.C. § 119 of Korean Patent Application No. 10-2023-0036584, filed on Mar. 21, 2023, the entire contents of which are hereby incorporated by reference.

### BACKGROUND

The present disclosure herein relates to a display panel.

Multimedia electronic devices such as televisions, mobile phones, tablets, computers, navigation devices, game machines, and the like are provided with a display panel for displaying an image.

The display panel includes a light-emitting element and a circuit for driving the light-emitting element. Light-emitting elements included in the display panel emit light and generate an image according to a voltage applied from the circuit. Researches about a connection between the light-emitting elements and the circuit are carried out in order to improve the reliability of the display panel.

### SUMMARY

The present disclosure may provide a display panel capable of preventing damage to an organic layer when patterning a connection line.

The present disclosure may also provide a display panel capable of preventing electrode disconnection due to damage to an organic layer.

The present disclosure may also provides a display panel capable of preventing deterioration of reliability of display quality.

An embodiment of a display panel includes: a light-emitting element including a first electrode, a second electrode arranged on the first electrode, and an intermediate layer arranged between the first electrode and the second electrode; a transistor electrically connected to the light-emitting element; a connection line arranged between the light-emitting element and the transistor in a cross-sectional view and including a driving connection part connected to the transistor and an emission connection part connected to the second electrode; a first organic layer arranged between the transistor and the connection line; a second organic layer arranged on the first organic layer and between the transistor and the light-emitting element; and a pixel defining layer arranged between the first electrode and the second electrode and having defined therein a first opening overlapping at least a portion of the first electrode and a second opening spaced apart from the first opening, wherein the second electrode includes one end connected to the emission connection part and another end spaced apart from the one end in a cross-sectional view.

In an embodiment, the connection line may include: a first pattern layer contacting the first organic layer and including a transparent conductive oxide; and a second pattern layer arranged on the first pattern layer.

In an embodiment, the second pattern layer may include: a first layer including titanium (Ti); a second layer arranged on the first layer and including aluminum (Al); and a third layer arranged on the second layer and including titanium (Ti).

In an embodiment, the second pattern layer may include: a first pattern arranged on the driving connection part; and a second pattern spaced apart from the first pattern and arranged on the emission connection part.

In an embodiment, the second pattern may include a tip part.

In an embodiment, the display panel may further include a protective layer arranged between the first organic layer and the connection line and including silicon, wherein the connection line may penetrate the first organic layer and the protective layer and may be connected to the transistor.

In an embodiment, the second organic layer may be arranged on the protective layer, the second opening may overlap the emission connection part, and at least a portion of the protective layer may be exposed by the second opening.

In an embodiment, the protective layer may have a thickness of about 500 Å to about 5000 Å.

In an embodiment, the connection line may be arranged between the first organic layer and the second organic layer, and a step may be defined between the emission connection part and the second organic layer.

In an embodiment, the display panel may further include a capping pattern overlapping the second opening and covering at least a portion of the emission connection part.

In an embodiment, the connection line may be arranged between the first organic layer and the pixel defining layer, and a step may be defined between the emission connection part and the pixel defining layer.

In an embodiment, the connection line may include: a first line arranged on the first organic layer; and a second line arranged on the second organic layer and having a step defined between the second line and the pixel defining layer.

in an embodiment, the light-emitting element may be provided in plurality, and the first electrodes of the plurality of light-emitting elements may be connected to each other.

In an embodiment, the second electrodes of the plurality of light-emitting elements may be separated from each other.

An embodiment of a display panel includes: a light-emitting element including a first electrode, a second electrode arranged on the first electrode, and an intermediate layer arranged between the first electrode and the second electrode; a transistor electrically connected to the light-emitting element; a connection line arranged between the light-emitting element and the transistor in a cross-sectional view and including a driving connection part connected to the transistor and an emission connection part connected to the second electrode and having a tip part defined therein; and a first organic layer arranged between the transistor and the connection line, wherein the connection line includes a first pattern layer contacting the first organic layer and including a transparent conductive oxide and a second pattern layer arranged on the first pattern layer.

In an embodiment, the second pattern layer may include: a first layer including titanium (Ti); a second layer arranged on the first layer and including aluminum (Al); and a third layer arranged on the second layer and including titanium (Ti).

In an embodiment, the second pattern layer may include: a first pattern arranged the driving connection part; and a second pattern spaced apart from the first pattern, arranged on the emission connection part, and including the tip part.

In an embodiment, the display panel may further include: a pixel defining layer arranged between the first electrode and the second electrode and having defined therein a first opening overlapping at least a portion of the first electrode and a second opening spaced apart from the first opening; and a capping pattern overlapping the second opening and covering at least a portion of the emission connection part.

An embodiment of a display panel includes: a light-emitting element including a first electrode, a second electrode arranged on the first electrode, and an intermediate layer arranged between the first electrode and the second electrode; a transistor electrically connected to the light-emitting element; a connection line arranged between the light-emitting element and the transistor in a cross-sectional view and including a driving connection part connected to the transistor and an emission connection part connected to the second electrode and having a tip part defined therein; a first organic layer arranged between the transistor and the connection line; and a protective layer arranged between the first organic layer and the connection line and including silicon.

In an embodiment, the display panel may further include: a second organic layer arranged on the protective layer and between the transistor and the light-emitting element; and a pixel defining layer arranged between the first electrode and the second electrode and having defined therein a first opening overlapping at least a portion of the first electrode and a second opening spaced apart from the first opening, wherein the second opening may overlap the emission connection part, and at least a portion of the protective layer may be exposed by the second opening may be provided.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram illustrating a display device according to an embodiment of the inventive concept;

FIGS. 2A and 2B are equivalent circuit diagrams of a pixel according to an embodiment of the inventive concept;

FIGS. 3A and 3B are plan views illustrating a display panel according to an embodiment of the inventive concept;

FIGS. 4A, 4B and 4C are enlarged plan views of a portion of a display panel according to an embodiment of the inventive concept;

FIG. 5 is a cross-sectional view illustrating a display panel according to an embodiment of the inventive concept;

FIGS. 6A and 6B are enlarged cross-sectional views of portions of a display panel according to an embodiment of the inventive concept;

FIG. 7 is a cross-sectional view of a display panel according to an embodiment of the inventive concept;

FIG. 8 is a cross-sectional view of a display panel according to an embodiment of the inventive concept;

FIG. 9 is a cross-sectional view illustrating a display panel according to an embodiment of the inventive concept;

FIG. 10 is a cross-sectional view of a display panel according to an embodiment of the inventive concept;

FIG. 11 is a cross-sectional view of a display panel according to an embodiment of the inventive concept;

FIG. 12A is a cross-sectional view illustrating a display panel according to an embodiment of the inventive concept; and

FIG. 12B is an enlarged cross-sectional view of a portion of a display panel according to an embodiment of the inventive concept.

### DETAILED DESCRIPTION

It will be understood that when an element (or a region, layer, portion, or the like) is referred to as being “on”, “connected to”, or “coupled to” another element, it can be directly on or directly connected/coupled to the other element, or a third element may be present therebetween.

The same reference numerals refer to the same elements. In the drawings, the thicknesses, ratios, and dimensions of elements are exaggerated for clarity of illustration.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

The terms “first”, “second” and the like may be used for describing various elements, but the elements should not be construed as being limited by the terms. Such terms are only used for distinguishing one element from other elements. The terms of a singular form may include plural forms unless otherwise specified.

Furthermore, the terms “under”, “lower side”, “on”, “upper side”, and the like are used to describe association relationships among elements illustrated in the drawings. The terms, which are relative concepts, are used on the basis of directions illustrated in the drawings.

It will be further understood that the terms “comprise”, “comprising”, “include”, “including”, “has”, “having”, and the like, when used in this specification, specify the presence of stated features, numbers, steps, operations, elements, components, or combinations thereof, but do not preclude the presence or addition of one or more other features, numbers, steps, operations, elements, components, or combinations thereof.

Hereinafter, a display panel and a method for manufacturing the same according to an embodiment of the inventive concept will be described with reference to the accompanying drawings.

Hereinafter, embodiments of the inventive concept will be described in detail with reference to the accompanying drawings.

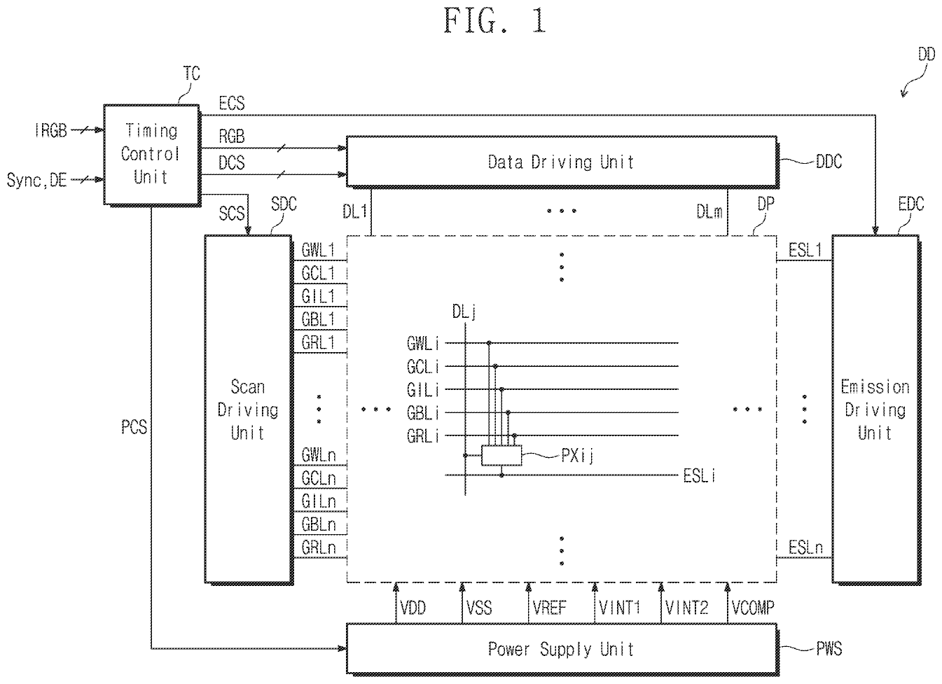

FIG. 1 is a block diagram illustrating a display device DD according to an embodiment of the inventive concept.

Referring to FIG. 1, the display device DD may include a display panel DP, a panel driving units SDC, EDC, and DDC, a power supply unit PWS, and a timing control unit TC. In the present embodiment, the display panel DP is described as an emissive display panel. The emissive display panel may include an organic light-emitting display panel, an inorganic light-emitting display panel, or a quantum dot light-emitting display panel. In the following embodiments, the organic light-emitting display panel will be described in detail as an example. The panel driving units may include a scan driving unit SDC, an emission driving unit EDC, and a data driving unit DDC.

The display panel DP may include scan lines GWL1 to GWLn, GCL1 to GCLn, GIL1 to GILn, GBL1 to GBLn, and GRL1 to GRLn, emission lines ESL1 to ESLn, and data lines DLI to DLm. The display panel DP may include a plurality of pixels connected to the scan lines GWL1 to GWLn, GCL1 to GCLn, GIL1 to GILn, GBL1 to GBLn, and GRL1 to GRLn, emission lines ESL1 to ESLn, and data lines DLI to DLm (where m and n are integers larger than 1).

For example, a pixel PXij (where i and j are integers larger than 1) positioned at an i-th horizontal line (or i-th pixel row) and a j-th vertical line (or j-th pixel column) may be connected to an i-th first scan line (or write scan line GWLi), an i-th second scan line (or compensation scan line GCLi), an i-th third scan line (or first initialization scan line GILi), an i-th fourth scan line (or second initialization scan line GBLi), an i-th fifth scan line (or reset scan line GRLi), a j-th data line DLj, and an i-th emission line ESLi.

The pixel PXij may include a plurality of light-emitting elements, a plurality of transistors, and a plurality of capacitors. The pixel PXij may be supplied with a first power supply voltage VDD, a second power supply voltage VSS, a third power supply voltage (or reference voltage) VREF, a fourth power supply voltage (or first initialization voltage) VINT1, a fifth power supply voltage (or second initialization voltage) VINT2, and a sixth power supply voltage (or compensation voltage) VCOMP through the power supply unit PWS.

Voltage values of the first power supply voltage VDD and the second power supply voltage VSS are set so as to cause a light-emitting element to emit light by allowing current to flow therethrough. For example, the first power supply voltage VDD may be set higher than the second power supply voltage VSS.

The third power supply voltage VREF may be a voltage for initializing a gate of a driving transistor included in the pixel PXij. The third power supply voltage VREF may be used to achieve a predetermined gradation using a voltage difference between a data signal and the third power supply voltage VREF. To this end, the third power supply voltage VREF may be set to a predetermined voltage within a voltage range of a data signal.

The fourth power supply voltage VINT1 may be a voltage for initializing a capacitor included in the pixel PXij. The fourth power supply voltage VINT1 may be set lower than the third power supply voltage VREF. For example, the fourth power supply voltage VINT1 may be set to a voltage lower than a difference between the third power supply voltage VREF and a threshold voltage of a driving transistor. However, an embodiment of the inventive concept is not limited thereto.

The fifth power supply voltage VINT2 may be a voltage for initializing a cathode of a light-emitting element included in the pixel PXij. The fifth power supply voltage VINT2 may be set to a voltage lower than the first power supply voltage VDD or the fourth power supply voltage VINT1 or a voltage that is similar or equal to the third power supply voltage VREF, but is not limited thereto and may be set to a voltage that is similar or equal to the first power supply voltage VDD.

The sixth power supply voltage VCOMP may supply a predetermined current to a driving transistor when compensating a threshold voltage of the driving transistor.

Meanwhile, although FIG. 1 illustrates that all of the first to sixth power supply voltages VDD, VSS, VREF, VINT1, VINT2, and VCOMP are supplied from the power supply unit PWS, an embodiment of the inventive concept is not limited thereto. For example, the first power supply voltage VDD and the second power supply voltage VSS both may be supplied regardless of a structure of the pixel PXij, and at least one of the third power supply voltage VREF, the fourth power supply voltage VINT1, the fifth power supply voltage VINT2, or the sixth power supply voltage VCOMP may not be supplied according to the structure of the pixel PXij.

In an embodiment of the inventive concept, signal lines connected to the pixel PXij may be variously configured according to a circuit structure of the pixel PXij.

The scan driving unit SDC may receive a first control signal SCS from the timing control unit TC, and may supply a scan signal to each of the first scan lines GWL1 to GWLn, second scan lines GCL1 to GCLn, third scan lines GIL1 to GILn, fourth scan lines GBL1 to GBLn, and fifth scan lines GRL1 to GRLn on the basis of the first control signal SCS.

The scan signal may be set to a voltage at which transistors supplied with the scan signal may be turned on. For example, the scan signal supplied to a P-type transistor may be set to a logic low level, and the scan signal supplied to an N-type transistor may be set to a logic high level. Hereinafter, the wording “scan signal is supplied” may indicate that the scan signal is supplied at a logic level at which a transistor controlled by the scan signal is turned on.

For convenience, FIG. 1 illustrates the scan driving unit SDC as a single element, but an embodiment of the inventive concept is not limited thereto. According to the embodiment, a plurality of scan driving units may be included to supply the scan signal to each of the first scan lines GWL1 to GWLn, second scan lines GCL1 to GCLn, third scan lines GIL1 to GILn, fourth scan lines GBL1 to GBLn, and fifth scan lines GRL1 to GRLn.

The emission driving unit EDC may supply an emission signal to the emission lines ESL1 to ESLn on the basis of a second control signal ECS. For example, the emission signal may be sequentially supplied to the emission lines ESL1 to ESLn.

Transistors connected to the emission lines ESL1 to ESLn of an embodiment of the inventive concept may be configured with N-type transistors. Here, the emission signal supplied to the emission lines ESL1 to ESLn may be set to a gate off voltage. Transistors that receive the emission signal may be turned off when the emission signal is supplied, otherwise may be set to a turn on state.

The second control signal ECS may include an emission start signal and clock signals, and the emission driving unit EDC may be implemented as a shift register that sequentially generates and outputs pulse-type emission signals by sequentially shifting the pulse-type emission start signal using the clock signals.

The data driving unit DDC may receive a third control signal DCS and image data RGB from the timing control unit TC. The data driving unit DDC may convert the image data RGB of a digital format into an analog data signal (i.e., data signal). The data driving unit DDC may supply a data signal to the data lines DLI to DLm according to the third control signal DCS.

The third control signal DCS may include a data clock signal, a horizontal start signal, and a data enable signal instructing output of a valid data signal. For example, the data driving unit DDC may include a shift register that generates a sampling signal by shifting the horizontal start signal in synchronization with the data clock signal, a latch that latches the image data RGB in response to the sampling signal, a digital-to-analog converter (or decoder) that converts the latched image data (e.g., digital data) into analog data signals, and buffers (or amplifiers) that output the data signals to the data lines DLI to DLm.

The power supply unit PWS may supply the display panel DP with the first power supply voltage VDD, the second power supply voltage VSS, and the third power supply voltage VREF for driving the pixel PXij. Furthermore, the power supply unit PWS may supply the display panel DP with at least one of the fourth power supply voltage VINT1, the fifth power supply voltage VINT2, or the sixth power supply voltage VCOMP.

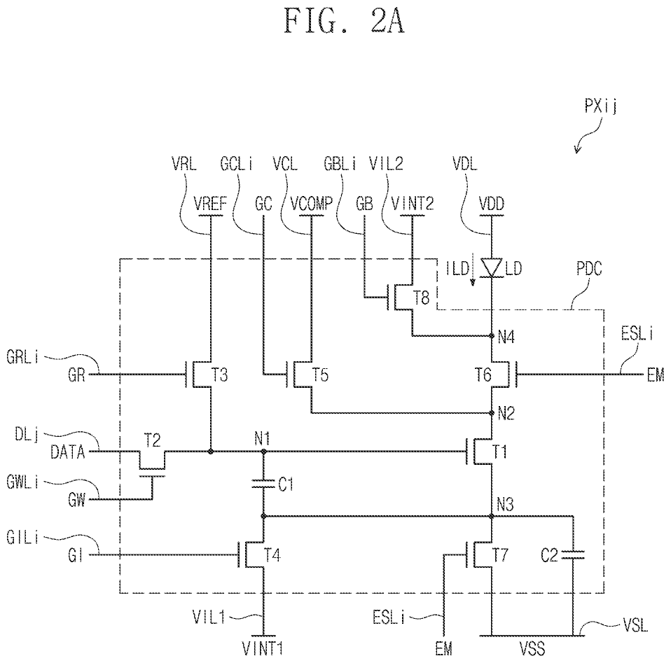

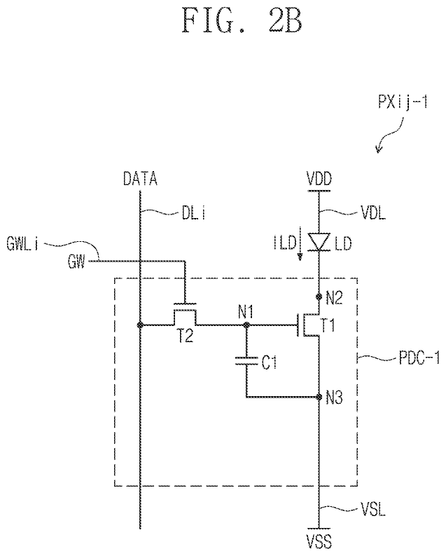

For example, the power supply unit PWS may supply each of the first power supply voltage VDD, the second power supply voltage VSS, the third power supply voltage VREF, the fourth power supply voltage VINT1, the fifth power supply voltage VINT2, and the sixth power supply voltage VCOMP to the display panel DP via a first power supply line VDL (see FIG. 2A), a second power supply line VSL (see FIG. 2A), a third power supply line (or reference voltage line) VRL (see FIG. 2A), a fourth power supply line (or first initialization voltage line) VIL1 (see FIG. 2A), a fifth power supply line (or second initialization voltage line) VIL2 (see FIG. 2A), and a sixth power supply line (or compensation voltage line) VCL (see FIG. 2A), which are not shown.

The power supply unit PWS may be implemented as a power management integrated circuit, but is not limited thereto.

The timing control unit TC may generate the first control signal SCS, the second control signal ECS, the third control signal DCS, and a fourth control signal PCS on the basis of input image data IRGB, a synchronization signal Sync (e.g., vertical synchronization signal, horizontal synchronization signal, etc.), a data enable signal DE, and a clock signal. The first control signal SCS may be supplied to the scan driving unit SDC, the second control signal ECS may be supplied to the emission driving unit EDC, the third control signal DCS may be supplied to the data driving unit DDC, and the fourth control signal PCS may be supplied to the power supply unit PWS. The timing control unit TC may generate the image data RGB (or frame data) by re-sorting the input image data IRGB according to arrangement of the pixels PXij in the display panel DP.

Meanwhile, the scan driving unit SDC, the emission driving unit EDC, the data driving unit DDC, the power supply unit PWS, or the timing control unit TC may be directly formed in the display panel DP, or may be provided in a form of a separate driving chip and connected to the display panel DP. Furthermore, at least two of the scan driving unit SDC, the emission driving unit EDC, the data driving unit DDC, the power supply unit PWS, and the timing control unit TC may be provided as a single driving chip. For example, the data driving unit DDC and the timing control unit TC may be provided as a single driving chip.

The display device DD according to an embodiment has been described with reference to FIG. 1, but the display device of an embodiment of the inventive concept is not limited thereto. Signal lines may be further added or omitted according to a configuration of pixels. Furthermore, a connection relationship between a single pixel and signal lines may be changed. When any one of signal lines is omitted, another signal line may replace the omitted signal line.

FIGS. 2A and 2B are equivalent circuit diagrams of a pixel according to an embodiment. FIGS. 2A and 2B illustrate examples of equivalent circuit diagrams of the pixels PXij and PXij-1 connected to the i-th first scan line GWLi (hereinafter first scan line) and the j-th data line DLj (hereinafter data line).

As illustrated in FIG. 2A, the pixel PXij includes a light-emitting element LD and a pixel driving unit PDC. The light-emitting element LD is connected to the first power supply line VDL and the pixel driving unit PDC.

The pixel driving unit PDC may be connected to the plurality of scan lines GWLi, GCLi, GILi, GBLi, and GRLi, the data line DLj, the emission line ESLi, and the plurality of power supply lines VDL, VSL, VIL1, VIL2, VRL, and VCL. The pixel driving unit PDC may include first to eighth transistors T1 to T8, a first capacitor C1, and a second capacitor C2. Hereinafter, the first to eighth transistors T1 to T8 are all assumed to be N-type transistors. However, an embodiment of the inventive concept is not limited thereto, and some of the first to eighth transistors T1 to T8 may be N-type transistors and the others may be P-type transistors, or the first to eighth transistors T1 to T8 each may be P-type transistors.

A gate of the first transistor T1 may be connected to a first node N1. A first electrode of the first transistor T1 may be connected to a second node N2, and a second electrode may be connected to a third node N3. The first transistor T1 may be a driving transistor. The first transistor T1 may control a driving current ILD flowing from the first power supply line VDL to the second power supply line VSL via the light-emitting element LD according to a voltage of the first node N1. Here, the first power supply voltage VDD may be set to a voltage having higher potential than the second power supply voltage VSS.

In the present disclosure, “electrically connecting between a transistor and a signal line or between a transistor and another transistor” represents that “a source, drain, and gate of a transistor have an integrated form with a signal line or are connected thereto via a connection electrode”

The second transistor T2 may include a gate connected to the write scan line GWLi, a first electrode connected to the date line DLj, and a second electrode connected to the first node N1. The second transistor T2 may supply a data signal DATA to the first node N1 in response to the write scan signal GW transferred through the write scan line GWLi. When the write scan signal GW is supplied to the write scan line GWLi, the second transistor T2 may be turned on so as to electrically connect the data line DLj and the first node N1.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In the present embodiment, a gate of the third transistor T3 may receive a reset scan signal GR through the i-th fifth scan line GRLi (hereinafter fifth scan line). When the reset scan signal GR is supplied to the reset scan line GRLi, the third transistor T3 may be turned on so as to provide the reference voltage VREF to the first node N1.

The fourth transistor T4 may be connected between the third node N3 and the first initialization voltage line VIL1. A first electrode of the fourth transistor T4 may be connected to the third node N3, and a second electrode of the fourth transistor T4 may be connected to the first initialization voltage line VIL1 that provides the first initialization voltage VINT1. The fourth transistor T4 may be referred to as a first initialization transistor. A gate of the fourth transistor T4 may receive a first initialization scan signal GI through the i-th third scan line GILi (hereinafter third scan line). When the first initialization scan signal GI is supplied to the first initialization scan line GILi, the fourth transistor T4 may be turned on so as to supply the first initialization voltage VINT1 to the third node N3.

The fifth transistor T5 may be connected between the compensation voltage line VCL and the second node N2. A first electrode of the fifth transistor T5 may receive the compensation voltage VCOMP through the compensation voltage line VCL, and a second electrode of the fifth transistor T5 may be electrically connected to the first electrode of the first transistor T1 by being connected to the second node N2. A gate of the fifth transistor T5 may receive a compensation scan signal GC through the i-th second scan line GCLi (hereinafter second scan line). When the compensation scan signal GC is supplied to the compensation scan line GCLi, the fifth transistor T5 may be turned on so as to provide the compensation voltage VCOMP to the second node N2, and thus a threshold voltage of the first transistor T1 may be compensated during a compensation period.

The sixth transistor T6 may be connected between the first transistor T1 and the light-emitting element LD. In detail, a gate of the sixth transistor T6 may receive an emission signal EM through the i-th emission line ESLi (hereinafter emission line). A first electrode of the sixth transistor T6 may be connected to a cathode of the light-emitting element LD through a fourth node N4, and a second electrode of the sixth transistor T6 may be connected to the first electrode of the first transistor T1 through the second node N2. The sixth transistor T6 may be referred to as a first emission control transistor. When the emission signal EM is supplied to the sixth transistor T6, the sixth transistor T6 may be turned on so as to electrically connect the light-emitting element LD and the first transistor T1.

The seventh transistor T7 may be connected between the second power supply line VSL and the third node N3. A first electrode of the seventh transistor T7 may be connected to the second electrode of the first transistor T1 through the third node N3, and a second electrode of the seventh transistor T7 may receive the second power supply voltage VSS through the second power supply line VSL. A gate of the seventh transistor T7 may be electrically connected to the emission line ESLi. The seventh transistor T7 may be referred to as a second emission control transistor. When the emission signal EM is supplied to the emission line ESLi, the seventh transistor T7 may be turned on so as to electrically connect the second electrode of the first transistor T1 and the second power supply line VSL.

In the present embodiment, the sixth transistor T6 and the seventh transistor T7 are illustrated as being turned on through the same emission signal EM by being connected to the same emission line ESLi, but this is merely an example, and the sixth transistor T6 and the seventh transistor T7 may be independently turned on in response to different signals. Furthermore, in the pixel driving unit PDC according to an embodiment of the inventive concept, either the sixth transistor T6 or the seventh transistor T7 may be omitted.

The eighth transistor T8 may be connected between the second initialization voltage line VIL2 and the fourth node N4. The eighth transistor T8 may include a gate connected to the i-th fourth scan line GBLi (hereinafter fourth scan line), a first electrode connected to the second initialization voltage line VIL2, and a second electrode connected to the fourth node N4. The eighth transistor T8 may be referred to as a second initialization transistor. The eight transistor T8 may supply the second initialization voltage VINT2 to the fourth node N4 corresponding to the cathode of the light-emitting element LD in response to the second initialization scan signal GB transferred through the second initialization scan line GBLi. The cathode of the light-emitting element LD may be initialized by the second initialization voltage VINT2.

Meanwhile, in the present embodiment, some of the second to eighth transistor T2 to T8 may be simultaneously turned on through the same scan signal. For example, the eighth transistor T8 and the fifth transistor T5 may be simultaneously turned on through the same scan signal. For example, the eighth transistor T8 and the fifth transistor T5 may be operated by the same compensation scan signal GC. The eighth transistor T8 and the fifth transistor T5 may be simultaneously turned on/off by the same compensation scan signal GC. In this case, the compensation scan line GCLi and the second initialization scan line GBLi may be provided as a substantially single scan line. Accordingly, initialization of the cathode of the light-emitting element LD and compensation of the threshold voltage of the first transistor T1 may be performed at the same timing. However, this is merely an example, and the above-mentioned configuration is not limited to a certain embodiment.

Furthermore, according to an embodiment of the inventive concept, initialization of the cathode of the light-emitting element LD and compensation of the threshold voltage of the first transistor T1 may be performed by applying the same power supply voltage. For example, the compensation voltage line VCL and the second initialization voltage line VIL2 may be provided as a substantially single power supply voltage line. In this case, since an initialization operation of a cathode and a compensation operation of a driving transistor may be performed using one power supply voltage, a driving unit may be simply designed. However, this is merely an example, and the above-mentioned configuration is not limited to a certain embodiment.

A first capacitor C1 may be arranged between the first node N1 and the third node N3. The first capacitor C1 may store a differential voltage between the first node N1 and the third node N3. The first capacitor C1 may be referred to as a storage capacitor.

A second capacitor C2 may be arranged between the third node N3 and the second power supply line VSL. That is, one electrode of the second capacitor C2 may be connected to the second power supply line VSL supplied with the second power supply voltage VSS, and the other electrode of the second capacitor C2 may be connected to the third node N3. The second capacitor C2 may store charge corresponding to a voltage difference between the second power supply voltage VSS and the second node N2. The second capacitor C2 may be referred to as a hold capacitor. The second capacitor C2 may have high capacitance compared to the first capacitor C1. Accordingly, the second capacitor C2 may minimize a voltage change of the third node N3 in response to a voltage change of the first node N1.

In the present embodiment, the light-emitting element LD may be connected to the pixel driving unit PDC through the fourth node N4. The light-emitting element LD may include an anode connected to the first power supply line VDL and the cathode opposing the anode. In the present embodiment, the light-emitting element LD may be connected to the pixel driving unit PDC through the cathode. That is, in the pixel PXij according to an embodiment of the inventive concept, a connection node at which the light-emitting element LD and the pixel driving unit PDC are connected may be the fourth node N4, and the fourth node N4 may correspond to a connection node between the first electrode of the sixth transistor T6 and the cathode of the light-emitting element LD. Accordingly, potential of the fourth node N4 may substantially correspond to cathode potential of the light-emitting element LD.

In detail, the anode of the light-emitting element LD may be connected to the first power supply line VDL so that the first power supply voltage VDD that is a constant voltage is applied, and the cathode may be connected to the first transistor T1 through the sixth transistor T6. That is, in the present embodiment in which the first to eighth transistors T1 to T8 are N-type transistors, potential of the third node N3 corresponding to the source of the first transistor T1 that is a driving transistor may not be directly affected by characteristics of the light-emitting element LD. Therefore, even if the light-emitting element LD deteriorates, influence of the deterioration on a gate-source voltage Vgs of transistors constituting the pixel driving unit PDC, particularly a driving transistor, may reduce. That is, since a variation in a driving current due to the deterioration of the light-emitting element LD may reduce, an image sticking defect of a display panel due to an increase in use time may reduce, and a lifespan of the display panel may be improved.

Alternatively, as illustrated in FIG. 2B, the pixel PXij-1 may include a pixel driving unit PDC-1 including two transistors T1 and T2 and one capacitor C1. The pixel driving unit PDC-1 may be connected to the light-emitting element LD, the write scan line GWLi, the data line DLj, and the second power supply line VSL. The pixel driving unit PDC-1 illustrated in FIG. 2B may correspond to the pixel driving unit PDC illustrated in FIG. 2A except for the third to eighth transistors T3 to T8 and the second capacitor C2.

The first and second transistors T1 and T2 each may be N-type or P-type transistors. In the present embodiment, the first and second transistors T1 and T2 are assumed to be N-type transistors.

The first transistor T1 may include a gate connected to a first node N1, a first electrode connected to a second node N2, and a second electrode connected to a third node N3. The second node N2 may be a node connected to a side of the first power supply line VDL, and the third node N3 may be a node connected to a side of the second power supply line VSL. The first transistor T1 may be connected to the light-emitting element LD through the second node N2 and to the second power supply line VSL through the third node N3. The first transistor T1 may be a driving transistor.

The second transistor T2 may include a gate that receives the write scan signal GW through the write scan line GWLi, a first electrode connected to the date line DLj, and a second electrode connected to the first node N1. The second transistor T2 may supply a data signal DATA to the first node N1 in response to the write scan signal GW transferred through the write scan line GWLi.

The capacitor C1 may include an electrode connected to the first node N1 and another electrode connected to the third node N3. The capacitor C1 may store the data signal DATA transferred to the first node N1.

The light-emitting element LD may include an anode and a cathode. In the present embodiment, the anode of the light-emitting element LD is connected to the first power supply line VDL, and the cathode is connected to the pixel driving unit PDC-1 through the second node N2. In the present embodiment, the cathode of the light-emitting element LD may be connected to the first transistor T1. The light-emitting element LD may emit light according to an amount of current flowing through the first transistor T1.

In the present embodiment in which the first and second transistors T1 and T2 are N-type transistors, the second node N2 at which the cathode of the light-emitting element LD and the pixel driving unit PDC-1 are connected may correspond to the drain of the first transistor T1. That is, the gate-source voltage Vgs of the first transistor T1 may be prevented from being changed due to the light-emitting element LD. Accordingly, since a variation in a driving current due to the deterioration of the light-emitting element LD may reduce, an image sticking defect of a display panel due to an increase in use time may reduce, and a lifespan of the display panel may be improved.

Meanwhile, FIGS. 2A and 2B illustrate circuits of the pixel driving units PDC and PDC-1 according to an embodiment of the inventive concept, and the number and arrangement of transistors and the number and arrangement of capacitors may be variously designed in the circuits and are not limited to a certain embodiment, provided that the circuits are connected to the cathode of the light-emitting element LD in the display panel according to an embodiment of the inventive concept.

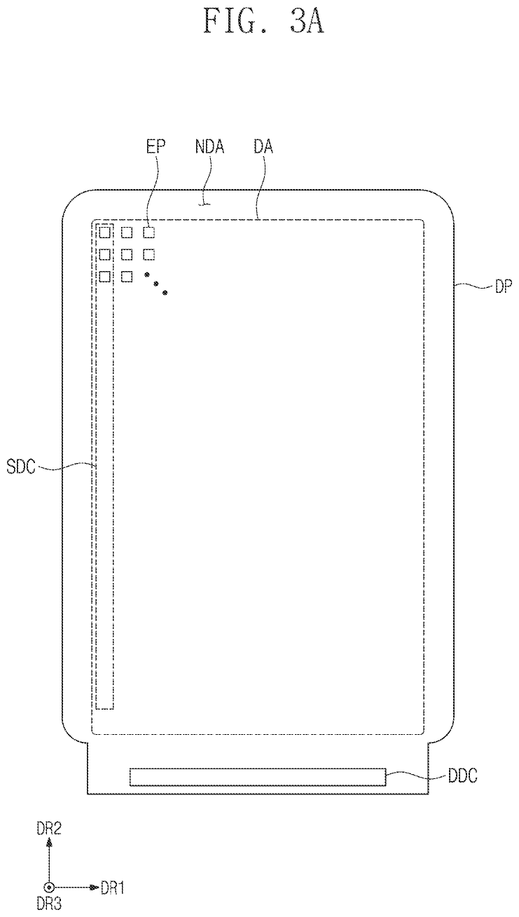

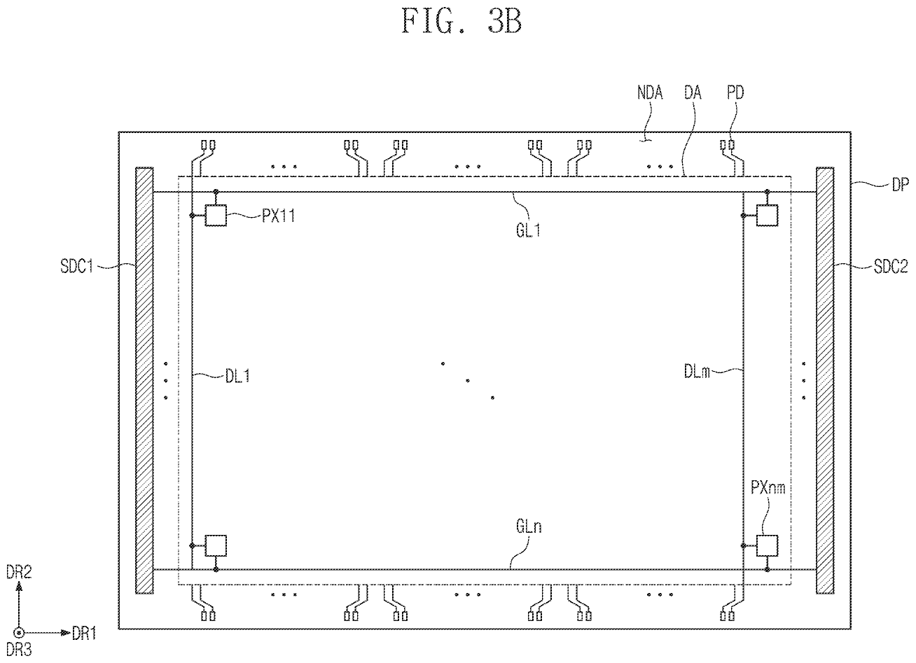

FIGS. 3A and 3B are plan views schematically illustrating a display panel according to an embodiment of the inventive concept. FIGS. 3A and 3B omit some of components. An embodiment of the inventive concept will be described with reference to FIGS. 3A and 3B.

Referring to FIG. 3A, the display panel DP of an embodiment may be divided into a display region DA and a peripheral region (or non-display region) NDA. The display region DA may include a plurality of emission parts EP.

The emission parts EP may be regions in which light is emitted by the pixels PXij (see FIG. 1). In detail, the emission parts EP each may correspond to the pixel defining layer opening OP-PDL that will be described later.

The peripheral region NDA may be arranged adjacent to the display region DA. In the present embodiment, the peripheral region NDA is illustrated in a shape surrounding an edge of the display region DA. However, this is merely an example, and the display region NDA may be arranged on one side of the display region DA or may be omitted, and is not limited to a certain embodiment.

In the present embodiment, the scan driving unit SDC and the data driving unit DDC may be mounted on the display panel DP. In an embodiment, the scan driving unit SDC may be arranged in the display region DA, and the data driving unit DDC may be arranged in the peripheral region NDA. The scan driving unit SDC may overlap, in a plan view, at least some of the plurality of emission parts EP arranged in the display region DA. Since the scan driving unit SDC is arranged in the display region DA, a size of the peripheral region NDA may reduce compared to a typical display panel in which the scan driving unit is arranged in the peripheral region, and a display device having a thin bezel may be easily implemented.

Meanwhile, unlike the illustration of FIG. 3A, the scan driving unit SDC may be provided as two separate parts. The two scan driving units SDC may be spaced apart laterally with a center of the display region DA therebetween. Alternatively, more than two scan driving units SDC may be provided, and the scan driving unit SDC is not limited to a certain embodiment.

Meanwhile, FIG. 3A illustrates an example of the display panel, and the data driving unit DDC may be arranged in the display region DA. Here, some of the emission parts EP arranged in the display region DA may overlap the data driving unit DDC in a plan view.

In an embodiment, the data driving unit DDC may be provided in a form of a driving chip independent of the display panel DP and may be connected to the display panel DP. However, this is merely an example, and the data driving unit DDC may be formed in the same process as the scan driving unit SDC so as to form the display panel DP, and is not limited to a certain embodiment.

As illustrated in FIG. 3B, a length of the display panel DP in a first direction DR1 may be larger than a length of the display panel DP in a second direction DR2. In the present embodiment, the display panel DP may include a plurality of scan driving units SDC1 and SDC2. The scan driving units SDC1 and SDC2 include, for example, a first scan driving unit SDC1 and a second scan driving unit SDC2 that are spaced apart in the first direction DR1.

The first scan driving unit SDC1 may be connected to a portion of the scan lines GL1 to GLn, and the second scan driving unit SDC2 may be connected to another portion of the scan lines GL1 to GLn. For example, the first scan driving unit SDC1 may be connected to odd-numbered scan lines among the scan lines GL1 to GLn, and the second scan driving unit SDC2 may be connected to even-numbered scan lines among the scan lines GL1 to GLn.

For easy description, pads PD of the data lines DLI to DLm are illustrated in FIG. 3B. The pads PD may be defined at ends of the data lines DLI to DLm. The data lines DLI to DLm may be connected to the data driving unit DDC (see FIG. 3A) through the pads PD.

According to an embodiment of the inventive concept, the pads PD may be divided and arranged at positions spaced apart from each other with the display region DA therebetween in the peripheral region NDA. For example, a portion of the pads PD may be arranged on an upper side, i.e., a side adjacent to the first scan line GL1 among the scan lines GL1 to GLn, and another portion of the pads PD may be arranged on a lower side, i.e., a side adjacent to the last scan line GLn among the scan lines GL1 to GLn. In the present embodiment, the pads PD connected to odd-numbered data lines among the data lines DLI to DLm may be arranged on an upper side, and the pads PD connected to even-numbered data lines among the data lines DLI to DLm may be arranged on a lower side.

Although not illustrated, the display panel DP may include a plurality of upper data driving units connected to the pads PD arranged on an upper side or a plurality of lower data driving units connected to the pads PD arranged on a lower side. However, this is merely an example, and the display panel DP may include one upper data driving unit connected to the pads PD arranged on an upper side or one lower data driving unit connected to the pads PD arranged on a lower side. That is, the pads PD according to an embodiment of the inventive concept may be arranged only on one side of the display panel DP and connected to a single data driving unit, and is not limited to a certain embodiment.

Alternatively, as described above with reference to FIG. 3A, the scan driving unit or the data driving unit may be arranged in the display region DA in the display panel DP of FIG. 3B, and thus, some of the emission parts arranged in the display region DA may overlap the scan driving unit or the data driving unit in a plan view.

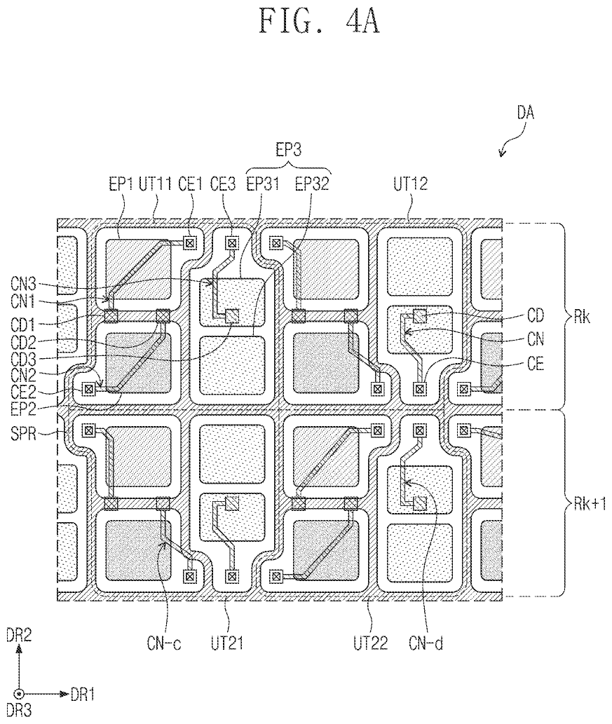

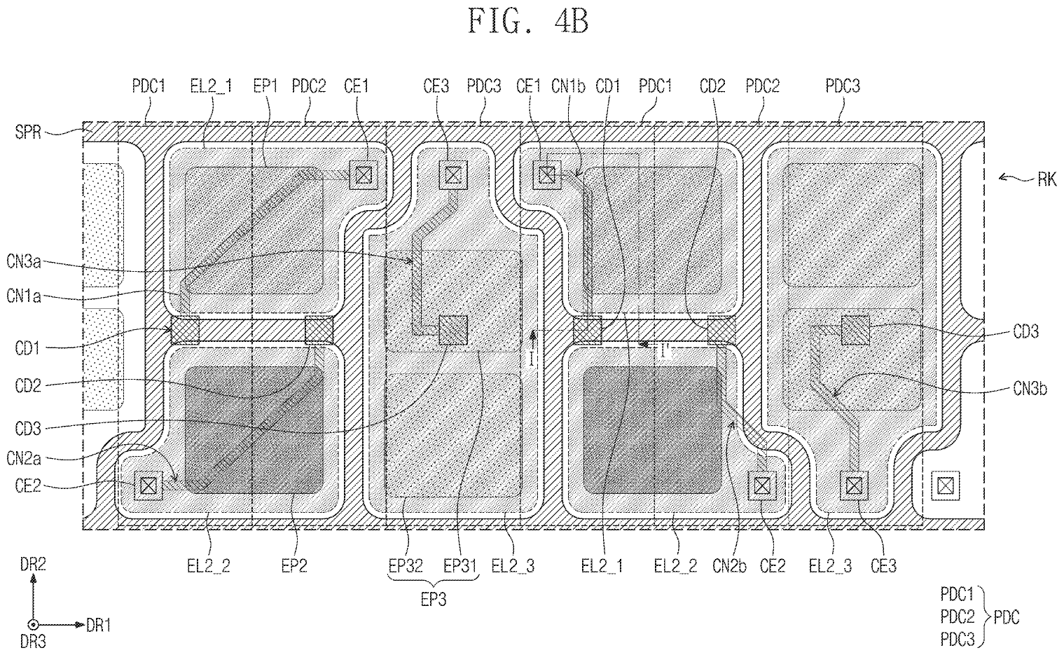

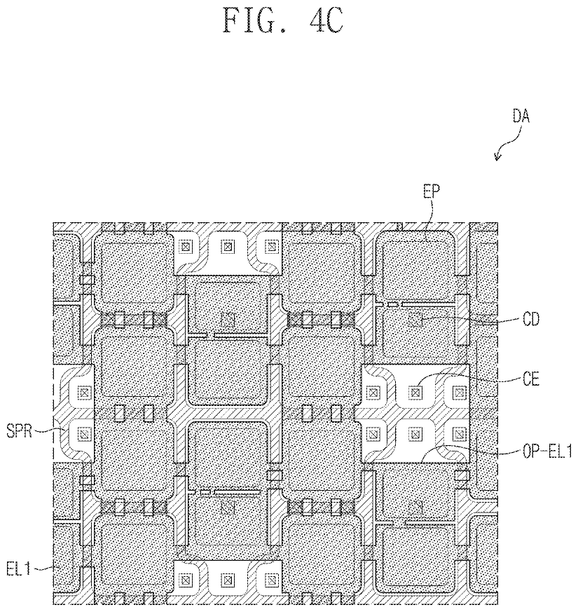

FIGS. 4A to 4C are enlarged plan views of a partial region of a display panel according to an embodiment. FIG. 4A illustrates a region in which a total of four light-emitting units UT are arranged in 2 by 2 array, and FIG. 4B illustrates an enlarged view of a portion of the region illustrated in FIG. 4A. Some of the elements illustrated in FIG. 4A are omitted or emphasized in FIG. 4C. An embodiment of the inventive concept will be described with reference to FIGS. 4A to 4C.

FIG. 4A illustrates a two-by-two array of light-emitting units UT11, UT12, UT21, and UT22. The emission parts of the first row Rk include emission parts constituting the first-row first-column light-emitting unit UT11 and the first-row second-column light-emitting unit UT12, and the emission parts of the second row Rk+1 include emission parts constituting the second-row first-column light-emitting unit UT21 and the second-row second-column light-emitting unit UT22.

FIG. 4B illustrates the emission parts in the first row Rk.

FIGS. 4A to 4C illustrate a separator SPR, a plurality of emission parts EP1, EP2, and EP3 arranged in regions divided by the separator SPR, connection lines CN1, CN2, and CN3, a first electrode EL1, and second electrodes EL2_1, EL2_2, and EL2_3.

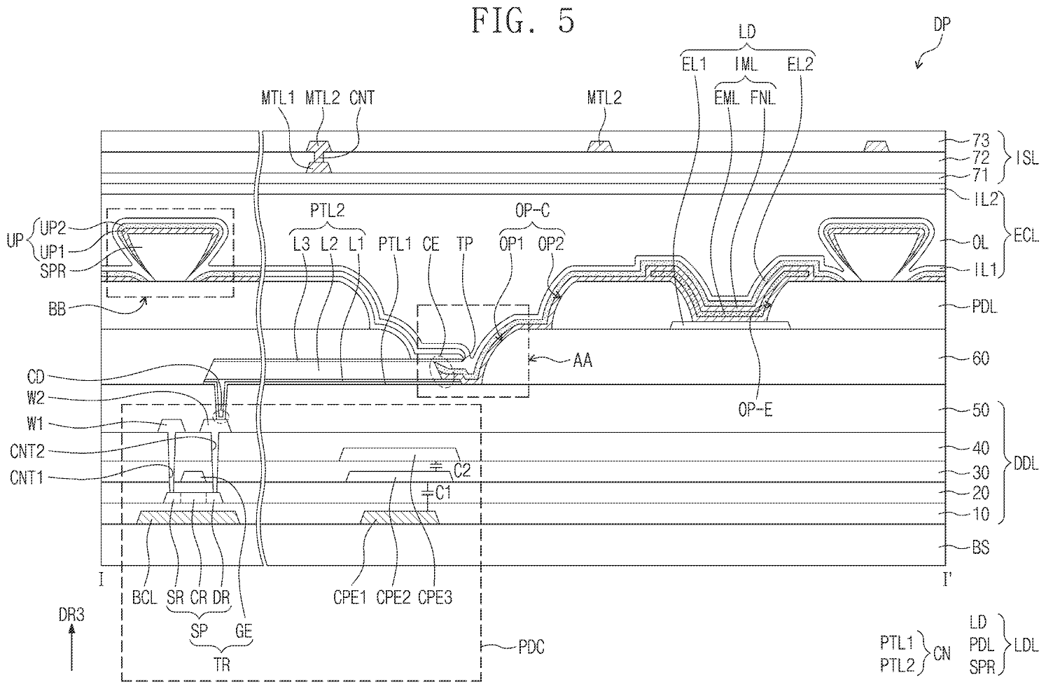

As described above, the emission parts EP1 to EP3 each may correspond to the pixel defining layer opening OP-PDL that will be described later. That is, the emission parts EP1 to EP3 each may be a region in which light is emitted by the above-mentioned light-emitting element, and may correspond to a unit constituting an image displayed on the display panel DP. In more detail, the emission parts EP1 to EP3 may correspond to a region defined by the pixel defining layer opening OP-PDL (FIG. 5) that will be described later, particularly, to a region defined by a lower surface of the pixel defining layer opening OP-PDL.

The emission parts EP1, EP2, and EP3 may include a first emission part EP1, a second emission part EP2, and a third emission part EP3. The first emission part EP1, the second emission part EP2, and the third emission part EP3 may emit beams of light of different colors. For example, the first emission part EP1 may emit red light, the second emission part EP2 may emit green light, and the third emission part EP3 may emit blue light, but a combination of colors is not limited thereto. Furthermore, at least two of the emission parts EP1, EP2, and EP3 may emit light of the same color. For example, all of the emission parts EP1, EP2, and EP3 may emit blue light or white light.

Meanwhile, the third emission part EP3 that displays light emitted by a third light-emitting element, among the emission parts EP1, EP2, and EP3, may include two sub-emission parts EP31 and EP32 spaced apart from each other in the second direction DR2. However, this is merely an example, the third emission part EP3 may be provided as one pattern having an integrated shape like the other emission parts EP1 and EP2, or at least one of the other emission parts EP1 and EP2 may include sub-emission parts spaced apart from each other, and a configuration of the emission parts is not limited to a certain embodiment.

In the present embodiment, the emission parts of the first row Rk may be configured in a form in which the first-row first-column light-emitting unit UT11 and the first-row second-column light-emitting unit UT12 are repeatedly arranged. The emission parts of the second row Rk+1 may be configured with emission parts having an arrangement and shape that are line symmetric to the emission parts of the first row Rk with respect to an axis parallel with the first direction DR1. Accordingly, the arrangement and shape, which are line symmetric to the emission parts constituting the first-row first-column light-emitting unit UT11 and the first-row second-column light-emitting unit UT12 and connection parts of connection lines with respect to an axis parallel with the first direction DR1, may correspond to the emission parts constituting the second-row first-column light-emitting unit UT21 and the second-row second-column light-emitting unit UT22 and connection parts of connection lines.

Hereinafter, the first-row first-column light-emitting unit UT11 will be described. For easy description, FIG. 4B illustrates a plurality of second electrodes EL2_1 to EL2_3, a plurality of pixel driving units PDC, and a plurality of connection lines CN. The second electrodes EL2_1 to EL2_3 may be electrically disconnected by being separated from each other by the separator SPR. In the present embodiment, a single light-emitting unit UT may include three emission parts EP1 to EP3. Accordingly, the light-emitting unit UT may include three second electrodes EL2_1 to EL2_3 (hereinafter first to third cathodes), three pixel driving units PDC1 to PDC3, and three connection lines CN1 to CN3. However, this is merely an example, and the number and arrangement of the light-emitting units UT may be variously designed, and are not limited to a certain embodiment.

The first to third pixel driving units PDC1 to PDC3 are electrically connected to light-emitting elements constituting the first to third emission parts EP1 to EP3, respectively. In the present disclosure, the term “connected” indicates not only direct physical connection but also electrical connection.

Furthermore, each of regions in which the pixel driving units PDC1 to PDC3 are defined in a plan view as illustrated in FIG. 4B may correspond to a unit in which transistor and capacitor elements constituting the circuit PDC (see FIG. 2) for driving a light-emitting element of a pixel are repeatedly arranged.

The first to third pixel driving units PDC1 to PDC3 may be arranged sequentially in the first direction DR1. Meanwhile, an arrangement position of the first to third pixel driving units PDC1 to PDC3 may be independently designed regardless of a position or shape of the first to third emission parts EP1 to EP3.

For example, the first to third pixel driving units PDC1 to PDC3 may be designed so as to be arranged in a region divided and defined by the separator, i.e., a position different from the position in which the first to third cathodes EL2_1 to EL2_3 are arranged, or to have an area size of a shape different from the shape of the first to third cathodes EL2_1 to EL2_3. Alternatively, the first to third pixel driving units PDC1 to PDC3 may be designed so as to be arranged overlapping the first to third emission parts EP1 to EP3, respectively, and to have a shape with an area size of a shape similar to a region divided and defined by the separator, for example, the first to third cathodes EL2_1 to EL2_3.

In the present embodiment, the first to third pixel driving units PDC1 to PDC3 each have a rectangular shape, the first to third emission parts EP1 to EP3 have a smaller area size than the first to third pixel driving units PDC1 to PDC3 and are arranged in a different form, and the first to third cathodes EL2_1 to EL2_3 have an irregular shape and are arranged overlapping the first to third emission parts EP1 to EP3.

Accordingly, as illustrated in FIG. 4B, the first pixel driving unit PDC1 may be arranged at a position partially overlapping the first emission part EP1, the second emission part EP2, and another adjacent light-emitting unit. The second pixel driving unit PDC2 may be arranged at a position overlapping the first emission part EP1, the second emission part EP2, and the third emission part EP3. The third pixel driving unit PDC3 may be arranged at a position overlapping the third emission part EP3. However, this is merely an example, and positions of the first to third pixel driving units PDC1 to PDC3 may be designed in various forms and arrangements independent of the emission parts EP1 to EP3, and are not limited to a certain embodiment.

The connection line CN may be provided in plurality and spaced apart from each other. The connection line CN may electrically connect a pixel driving unit and a light-emitting element. In detail, the connection line CN may correspond to the node (N4 of FIG. 2A or N2 of FIG. 2B) at which the light-emitting element LD is connected to the pixel driving unit PDC.

The connection line CN may include a first connection part (or emission connection part) CE and a second connection part (or driving connection part) CD. The emission connection part CE may be provided on one side of the connection line CN, and the driving connection part CD may be provided on another side of the connection line CN.

The driving connection part CD may be a portion of the connection line CN connected to the pixel driving unit PDC. In the present embodiment, the driving connection part CD may be connected to one electrode of a transistor constituting the pixel driving unit PDC. In detail, the driving connection part CD may be connected to the drain of the sixth transistor T6 illustrated in FIG. 2A or the drain of the first transistor T1 illustrated in FIG. 2B. Accordingly, a position of the driving connection part CD may correspond to a position of the transistor TR (see FIG. 5), physically connected to the connection line CN, in the pixel driving unit. The emission connection part CE may be a portion of the connection line CN connected to a light-emitting element. In the present embodiment, the emission connection part CE may be connected to the second electrode EL2 (hereinafter cathode) of a light-emitting element.

The light-emitting unit UT may include first to third connection lines CN1 to CN3. The first connection line CN1 may connect a light-emitting element forming the first emission part EP1 to the first pixel driving unit PDC1, the second connection line CN2 may connect a light-emitting element forming the second emission part EP2 to the second pixel driving unit PDC2, and the third connection line CN3 may connect a light-emitting element forming the third emission part EP3 to the third pixel driving unit PDC3.

In detail, the first to third connection lines CN1 to CN3 may respectively connect the first to third cathodes EL2_1 to EL2_3 to the first to third pixel driving units PDC1 to PDC3. The first connection line CN1 may include a first driving connection part CD1 connected to the first pixel driving unit PDC1 and a first emission connection part CE1 connected to the first cathode EL2_1. The second connection line CN2 may include a second driving connection part CD2 connected to the second pixel driving unit PDC2 and a second emission connection part CE2 connected to the second cathode EL2_2. The third connection line CN3 may include a third driving connection part CD3 connected to the third pixel driving unit PDC3 and a third emission connection part CE3 connected to the third cathode EL2_3.

The first to third driving connection parts CD1 to CD3 may be aligned in the first direction DR1. As described above, the first to third driving connection parts CD1 to CD3 may correspond to positions of connection transistors constituting the first to third pixel driving units PDC1 to PDC3, respectively. The connection transistor may be a transistor including, as one electrode, a connection node at which a pixel driving unit and a light-emitting element are connected in one pixel, and, for example, may correspond to the sixth transistor T6 of FIG. 2A or the first transistor T1 of FIG. 2B. According to an embodiment of the inventive concept, a shape, position, and arrangement of pixel driving units of all pixels may be simply configured and designed regardless of a shape, size, or emitted light color of an emission part.

In the present embodiment, the first to third emission connection parts CE1 to CE3 may be arranged at positions not overlapping the emission parts EP1 to EP3 in a plan view. As described below, the emission connection part CE (see FIG. 5) of the connection line CN is a portion to which the light-emitting element LD (see FIG. 5) is connected and in which a tip part TP (see FIG. 5) is formed, and is thus provided at a position not overlapping the pixel defining layer opening OP-PDL. That is, the emission connection parts CE to CE3 may be arranged at positions spaced apart from the emission parts EP1 to EP3 in the cathodes EL2_1 to EL2_3, and the cathodes EL2_1 to EL2_3 may include partial regions protruding from the emission parts EP1 to EP3 in a plan view in order to be connected to the connection lines CN1 to CN3 at positions at which the emission connection parts CE1 to CE3 are arranged.

For example, the first cathode EL2_1 may include a protrusion protruding from the first emission part EP1 at a position not overlapping the first emission part EP1 in order to be connected to the first connection line CN1 at a position at which the first emission connection part CE1 is arranged, and the first emission connection part CE1 may be provided to the protrusion.

Furthermore, the first pixel driving unit PDC1, particularly the first driving connection part CD1 at which the first connection line CN1 is connected to the transistor TR may be defined at a position not overlapping the first emission part EP1 in a plan view. According to the present embodiment, since the first connection part CN1 is arranged in the first emission part EP1, the first cathode EL2_1 and the first pixel driving unit PDC1 that are spaced apart may be easily connected.

Meanwhile, the third pixel driving unit PDC3, particularly the third driving connection part CD3 at which the third connection line CN3 is connected to the transistor TR may be defined at a position not overlapping the third emission connection part CE3 and arranged at a position overlapping the third emission part EP3 in a plan view. According to the present embodiment, since the third cathode EL2_3 and the pixel driving unit PDC3 are connected through the third connection line CN3, restrictions due to a position or shape of the third emission part EP3 may reduce when designing the pixel driving unit PDC3, thus improving the degree of design freedom.

Referring back to FIG. 4A, the emission parts of the second row Rk+1 may be configured with emission parts having an arrangement and shape that are line symmetric to the light-emitting units UT11 and UT12 of the first row with respect to an axis parallel with the first direction DR1. Here, due to characteristics of the shape and arrangement of the light-emitting units UT11 and UT12 of the first row, the light-emitting units UT21 and UT22 of the second row may be substantially configured with emission parts shifted from the light-emitting units UT11 and UT12 of the first row in the first direction DR1. That is, the second-row first-column light-emitting unit UT21 may be configured with emission parts having the same shape as the first-row second-column light-emitting unit UT12, and the second-row second-column light-emitting unit UT22 may be configured with emission parts having the same shape as the first-row second-column light-emitting unit UT12.

Accordingly, shapes and arrangement of connection lines CN-c arranged in the second-row first-column light-emitting unit UT21 may be the same as those of the connection lines CN1b, CN2b, and CN3b arranged in the first-row second-column light-emitting unit UT12. Likewise, shapes and arrangement of connection lines CN-d arranged in the second-row second-column light-emitting unit UT22 may be the same as those of the connection lines CN1a, CN2a, and CN3a arranged in the first-row first-column light-emitting unit UT11.

Meanwhile, referring to FIG. 4C, the first electrode EL1 (hereinafter anode) according to an embodiment of the inventive concept may be commonly provided to the plurality of emission parts EP1 to EP3. That is, the anode EL1 may be formed as a single layer that is overall integrated in the display region DA, and thus may be arranged overlapping the separator SPR. Alternatively, the anodes EL1 of light-emitting elements may be formed as independent conductive patterns spaced apart from each other and may be electrically connected to each other through another conductive layer, and thus the patterns of the anodes EL1 may be arranged without overlapping the separator SPR.

As described above, the first power supply voltage VDD may be applied to the anode EL1, and a common voltage may be provided to all of emission parts. The anode EL1 may be connected to the first power supply line VDL (see FIG. 2A) that provides the first power supply voltage VDD in the peripheral region NDA or may be connected to the first power supply line VDL in the display region DA, but is not limited to a certain embodiment.

Meanwhile, a plurality of openings may be defined in the anode EL1 according to the present embodiment, and the openings may penetrate a layer of the anode EL1. The openings of the layer of the anode EL1 may be arranged at a position not overlapping the emission parts EP, and may be generally defined at a position overlapping the separator SPR. The openings may facilitate discharge of gas generated in an organic layer arranged below the anode EL1, for example, the sixth insulating layer 60 (see FIG. 5) that will be described later. Accordingly, gas may be sufficiently discharged from an organic layer arranged below a light-emitting element during a manufacturing process of a display panel, and gas discharged from an organic layer may be reduced after manufacturing, and thus a deterioration rate of a light-emitting element may reduce.

According to an embodiment of the inventive concept, since a connection line is arranged between a light-emitting element and a pixel driving unit, the light-emitting element may be easily connected to the pixel driving unit only by changing a shape of a cathode without changing shapes or arrangement of emission parts. Therefore, a degree of design freedom for arrangement of the pixel driving unit may be improved, and an area size of an emission part of the display panel or resolution thereof may be easily increased.

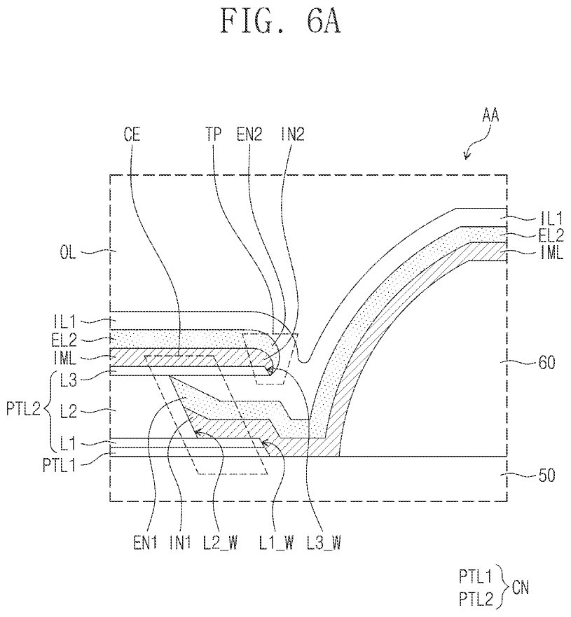

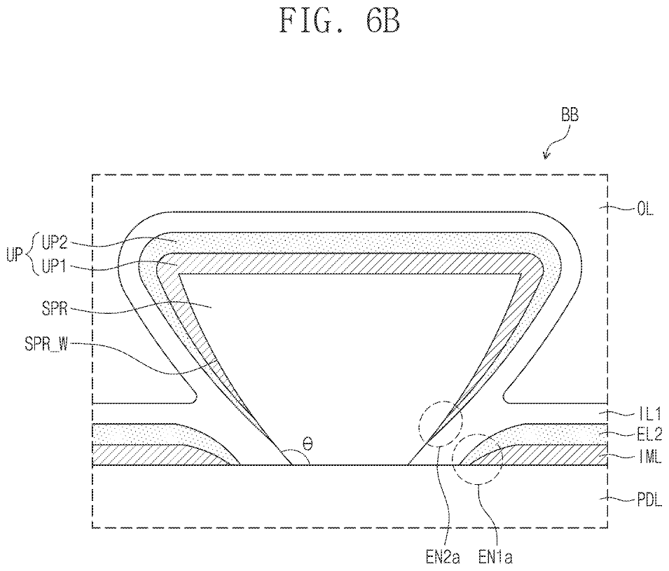

FIG. 5 is a cross-sectional view of a display panel according to an embodiment. FIG. 6A is an enlarged cross-sectional view of a partial region of a display panel according to an embodiment. FIG. 6B is an enlarged cross-sectional view of a partial region of a display panel according to an embodiment. FIG. 5 is a cross-sectional view taken along line I-I′ of FIG. 4B. FIG. 6A is an enlarged cross-sectional view of the region AA of FIG. 5, and FIG. 6B is an enlarged cross-sectional view of the region BB of FIG. 5. An embodiment of the inventive concept will be described with reference to FIGS. 5 to 6B.

Referring to FIG. 5, the display panel DP of an embodiment may include a base layer BS, a driving element layer DDL, a light-emitting element layer LDL, an encapsulation layer ECL, and a sensing layer ISL. The driving element layer DDL may include a plurality of insulating layers 10, 20, 30, 40, and 50 arranged on the base layer BS, and a plurality of conductive patterns and semiconductor patterns arranged between the insulating layers. The conductive patterns and semiconductor patterns may be arranged between the insulating layers to constitute the pixel driving unit PDC. For easy description, FIG. 5 illustrates a cross-section of a portion of a region in which one light-emitting unit is arranged.

The base layer BS may be a member that provides a base surface on which the pixel driving unit PDC is arranged. The base layer BS may be a rigid substrate or a flexible substrate that is bendable, foldable, or rollable. The base layer BS may be a glass substrate, a metal substrate, a polymer substrate, or the like. However, an embodiment of the inventive concept is not limited thereto, and the base layer BS may be an inorganic layer, an organic layer, or a composite material layer.

The base layer BS may have a multi-layer structure. The base layer BS may include a first polymer resin layer, a silicon oxide (SiOx) layer arranged on the first polymer resin layer, an amorphous silicon (a-Si) layer arranged on the silicon oxide layer, and a second polymer resin layer arranged on the amorphous silicon layer. The silicon oxide layer and the amorphous silicon layer may be referred to as a base barrier layer.

The polymer resin layers may include a polyimide-based resin. Furthermore, the polymer resin layers may include at least one of acrylate-based resin, methacrylate-based resin, polyisoprene-based resin, vinyl-based resin, epoxy-based resin, urethane-based resin, cellulose-based resin, siloxane-based resin, polyamide-based resin, or perylene-based resin. Herein, the term “ . . . -based resin” indicates inclusion of a functional group of “ . . . ”.

The insulating layers, conductive layers, and semiconductor layers arranged on the base layer BS may be formed by coating or deposition. Thereafter, a hole may be formed in an insulating layer or a semiconductor pattern, a conductive pattern, a signal line, etc. may be formed by selectively patterning an insulating layer, a semiconductor layer, and a conductive layer through photography processes.

The driving element layer DDL may include the first to fifth insulating layers 10 to 50 sequentially arranged on the base layer BS. FIG. 5 illustrates one transistor TR and two capacitors C1 and C2 of the pixel driving unit PDC. The transistor TR may correspond to a transistor connected to the light-emitting element LD through the connection line CN, i.e., a connection transistor connected to a node (the fourth node N4 of FIG. 2A or the second node N2 of FIG. 2B) corresponding to the cathode of the light-emitting element LD, and may specifically correspond to the sixth transistor T6 of FIG. 2A or the first transistor T1 of FIG. 2B. Meanwhile, although not illustrated, other transistors constituting the pixel driving unit PDC may have the same structure as the transistor TR (hereinafter connection transistor) illustrated in FIG. 5. However, this is merely an example, and the other transistors constituting the pixel driving unit PDC may have a different structure from that of the connection transistor TR, and are not limited to a certain embodiment.

The first insulating layer 10 may be arranged on the base layer BS. The first insulating layer 10 may be an inorganic layer or organic layer, and may have a single-layer or multi-layer structure. The first insulating layer 10 may include at least one of aluminum oxide, titanium oxide, silicon oxide, silicon nitride, silicon oxynitride, zirconium oxide, or hafnium oxide. In the present embodiment, the first insulating layer 10 is illustrated as a single layer of a silicon oxide. Meanwhile, the insulating layers that will be described layer may be an inorganic layer or organic, and may have a single-layer or multi-layer structure. The inorganic layer may include at least one of the above-mentioned materials, but is not limited thereto.

Meanwhile, the first insulating layer 10 may cover a lower conductive layer BCL. That is, the display panel may further include the lower conductive layer BCL arranged overlapping the connection transistor TR. The lower conductive layer BCL may prevent electric potential caused by a polarization phenomenon of the base layer BS from affecting the connection transistor TR. Furthermore, the lower conductive layer BCL may block light that is incident on the connection transistor TR from below. At least one of an inorganic layer or a buffer layer may be further arranged between the lower conductive layer BCL and the base layer BS.

The lower conductive layer BCL may include reflective metal. For example, the lower conductive layer BCL may include titanium (Ti), molybdenum (Mo), alloys containing molybdenum, aluminum (Al), alloys containing aluminum, aluminum nitride (AlN), tungsten (W), tungsten nitride (WN), copper (Cu), and the like.

In the present embodiment, while not shown in FIG. 5, the lower conductive layer BCL may be connected to the source of the transistor TR through a source electrode pattern W1. In this case, the lower conductive layer BCL may be synchronized with the source of the transistor TR. However, this is merely an example, and the lower conductive layer BCL may be connected to and synchronized with the gate of the transistor TR. Alternatively, the lower conductive layer BCL may be connected to another electrode and may independently receive a constant voltage or pulse signal. Alternatively, the lower conductive layer BCL may be provided in a form isolated from another conductive pattern. The lower conductive layer BCL according to an embodiment of the inventive concept may be provided in various forms, and is not limited to a certain embodiment.

The connection transistor TR may be arranged on the first insulating layer 10. The connection transistor TR may include a semiconductor pattern SP and a gate electrode GE. The semiconductor pattern SP may be arranged on the first insulating layer 10. The semiconductor pattern SP may include an oxide semiconductor. For example, the oxide semiconductor may include transparent conductive oxide (TCO) such as indium tin oxide (ITO), indium zinc oxide (IZO), indium gallium zinc oxide (IGZO), zinc oxide (ZnO) or indium oxide (In2O3). However, an embodiment of the inventive concept is not limited thereto, and the semiconductor pattern may include amorphous silicon, low-temperature polycrystalline silicon, or polycrystalline silicon.

The semiconductor pattern SP may include a source region SR, a drain region DE, and a channel region CR divided according to a degree of conductivity. The channel region CR may be a portion overlapping the gate electrode GE in a plan view. The source region SR and the drain region DR may be spaced apart from each other with the channel region CR therebetween. In the case where the semiconductor pattern SP is an oxide semiconductor, the source region SR and the drain region DR each may be a reduced region. Accordingly, the source region SR and the drain region DR have relatively high reducible metal content compared to the channel region CR. Alternatively, in the case where the semiconductor pattern SP is polycrystalline silicon, the source region SR and the drain region DR each may be a region doped at high concentration.

The source region SR and the drain region DR may have relatively high conductively compared to the channel region CR. The source region SR may correspond to the source electrode of the connection transistor TR, and the drain region DR may correspond to the drain electrode of the connection transistor TR. As illustrated in FIG. 5, additional source electrode pattern W1 and drain electrode pattern W2 respectively connected to the source region SR and the drain region DR may be further provided. In detail, the additional source electrode pattern W1 and drain electrode pattern W2 may be integrally formed with one of lines constituting the pixel driving unit PDC or PDC-1 (see FIGS. 2A and 2B), and are not limited to a certain embodiment.

The second insulating layer 20 may commonly overlap a plurality of pixels, and may cover the semiconductor pattern SP. The second insulating layer 20 may be an inorganic layer or organic layer, and may have a single-layer or multi-layer structure. The second insulating layer 20 may include at least one of aluminum oxide, titanium oxide, silicon oxide, silicon nitride, silicon oxynitride, zirconium oxide, or hafnium oxide. In the present embodiment, the second insulating layer 20 may be a single layer of a silicon oxide.

The gate electrode GE may be arranged on the second insulating layer 20. The gate electrode GE may correspond to the gate of the connection transistor TR. Furthermore, the gate electrode GE may be arranged on the semiconductor pattern SP. However, this is merely an example, and the gate electrode GE may also be arranged below the semiconductor pattern SP, and is not limited to a certain embodiment.

The gate electrode GE may include titanium (Ti), silver (Ag), molybdenum (Mo), aluminum (Al), aluminum nitride (AlN), tungsten (W), tungsten nitride (WN), copper (Cu), or an alloy thereof, but is not particularly limited thereto.

The third insulating layer 30 may be arranged on the gate electrode GE. The third insulating layer 30 may be an inorganic layer or organic layer, and may have a single-layer or multi-layer structure. The fourth insulating layer 40 may include at least one of aluminum oxide, titanium oxide, silicon oxide, silicon nitride, silicon oxynitride, zirconium oxide, or hafnium oxide.

A first capacitor electrode CPE1 and a second capacitor electrode CPE2 may constitute the first capacitor C1. The first capacitor electrode CPE1 and the second capacitor electrode CPE2 may be spaced apart from each other with the first insulating layer 10 and the second insulating layer 20 therebetween.

In the present embodiment, the first capacitor electrode CPE1 and the lower conductive layer BCL may have an integrated form. Furthermore, the second capacitor electrode CPE2 and the gate electrode GE may also have an integrated form.

A third capacitor electrode CPE3 may be arranged on the third insulating layer 30. The third capacitor electrode CPE3 may be spaced apart from and overlap, in a plan view, the second capacitor electrode CPE2 with the third insulating layer 30 therebetween. The third capacitor electrode CPE3 may constitute the second capacitor C2 with the second capacitor electrode CPE2.

The fourth insulating layer 40 may be arranged on the third insulating layer 30 and the third capacitor electrode CPE3. The fourth insulating layer 40 may be an inorganic layer or organic layer, and may have a single-layer or multi-layer structure. The fourth insulating layer 40 may include at least one of aluminum oxide, titanium oxide, silicon oxide, silicon nitride, silicon oxynitride, zirconium oxide, or hafnium oxide.

The source electrode pattern W1 and the drain electrode pattern W2 may be arranged on the fourth insulating layer 40. The source electrode pattern W1 may be connected to the source region SR of the connection transistor TR through a first contact hole CNT1, and the source electrode pattern W1 and the source region SR of the semiconductor pattern SP may function as the source of the connection transistor TR. The drain electrode pattern W2 may be connected to the drain region DR of the connection transistor TR through a second contact hole CNT2, and the drain electrode pattern W2 and the drain region DR of the semiconductor pattern SP may function as the drain of the connection transistor TR. The fifth insulating layer 50 may be arranged on the source electrode pattern W1 and the drain electrode pattern W2.

The connection line CN may be arranged on the fifth insulating layer 50. The connection line CN may electrically connect the pixel driving unit PDC and the light-emitting element LD. That is, the connection line CN may electrically connect the connection transistor TR and the light-emitting element LD. The connection line CN may be a connection node connecting the pixel driving unit PDC and the light-emitting element LD. That is, the connection line CN may correspond to the fourth node N4 (see FIG. 2A) illustrated in FIG. 2A or the second node N2 (see FIG. 2B) illustrated in FIG. 2B. This is merely an example, and provided that the connection line CN is connectable to the light-emitting element LD, the connection line CN may be defined as a connection node to various elements among elements constituting the pixel driving unit PDC according to design of the pixel driving unit PDC, and is not limited to a certain embodiment.

The connection line CN may include a first pattern layer PTL1 and a second pattern layer PTL2. The second pattern layer PTL2 may be arranged on the first pattern layer PTL1. Furthermore, the tip part TP may be defined on the second pattern layer PTL2. Hereinafter, the fifth insulating layer 50 may be referred to as a first organic layer.

The first pattern layer PTL1 may be arranged between the fifth insulating layer 50 and the second pattern layer PTL2 so as to prevent direct contact between the second pattern layer PTL2 and the fifth insulating layer 50. The first pattern layer PTL1 may cover at least a portion of the fifth insulating layer 50 so as to prevent damage to the fifth insulating layer 50 which may occur when forming a pattern of the connection line CN. Relevant descriptions will be provided later.

The sixth insulating layer 60 may be arranged on the connection line CN. The sixth insulating layer 60 may be arranged on the fifth insulating layer 50 and cover the connection line CN. The fifth insulating layer 50 and the sixth insulating layer 60 may each be an organic layer. For example, the fifth insulating layer 50 and the sixth insulating layer 60 each may include general polymers such as benzocyclobutene (BCB), polyimide, hexamethyldisiloxane (HMDSO), polymethylmethacrylate (PMMA), or polystyrene (PS), or a polymer derivative having a phenol group, an acrylic polymer, an imidic polymer, an arylether polymer, an amidic polymer, a fluoric polymer, a p-xylene polymer, a vinyl alcohol polymer, and a blend thereof. Hereinafter, the fifth insulating layer 50 and the sixth insulating layer 60 may be referred to as a first organic layer 50 and a second organic layer 60, respectively.

A first opening portion OP1 that exposes at least a portion of the connection line CN may be defined in the second organic layer 60. The connection line CN may be electrically connected to the light-emitting element LD through the portion exposed by the first opening portion OP1. That is, the connection line CN may electrically connect the connection transistor TR and the light-emitting element LD. Relevant detailed descriptions will be provided later. Meanwhile, in the display panel DP according to an embodiment of the inventive concept, the sixth insulating layer 60 may be omitted or provided in plurality, and is not limited to a certain embodiment.

The light-emitting element layer LDL may be arranged on the sixth insulating layer 60. The light-emitting element layer LDL may include a pixel defining layer PDL, the light-emitting element LD, and the separator SPR. The pixel defining layer PDL may be an organic layer. For example, the pixel defining layer PDL may include general polymers such as benzocyclobutene (BCB), polyimide, hexamethyldisiloxane (HMDSO), polymethylmethacrylate (PMMA), or polystyrene (PS), or a polymer derivative having a phenol group, an acrylic polymer, an imidic polymer, an arylether polymer, an amidic polymer, a fluoric polymer, a p-xylene polymer, a vinyl alcohol polymer, and a blend thereof.

In an embodiment, the pixel defining layer PDL may have a property of absorbing light, and may have, for example, black color. That is, the pixel defining layer PDL may include a black coloring agent. The black coloring agent may include a black dye or black pigment. The black coloring agent may include metals such as carbon black and chromium or oxides thereof. The pixel defining layer PDL may correspond to a light shielding pattern having a light shielding characteristic.

A first opening OP-E and a second opening portion OP2 may be defined in the pixel defining layer PDL. The first opening OP-E and the second opening portion OP2 may be defined in each emission part. The first opening OP-E exposes at least a portion of the first electrode EL1 that will be described later. The first opening OP-E may be provided in plurality and arranged in correspondence with each of the light-emitting elements LD. The first opening OP-E may be a region in which all of components of the light-emitting element LD overlap and light emitted from the light-emitting element LD is substantially displayed. Accordingly, a shape of the above-mentioned emission part EP (see FIG. 3A) may substantially correspond to a shape of the first opening OP-E in a plan view. Hereinafter, the first opening OP-E may be referred to as an emission opening.

The second opening portion OP2 may be spaced apart from the emission opening OP-E in a plan view. In the present embodiment, the second opening portion OP2 may overlap the first opening portion OP1 of the second organic layer 60 in a plan view. A width of the second opening portion OP2 may be larger than a width of the first opening portion OP1. The second opening portion OP2 and the first opening portion OP1 may be connected in a thickness direction so as to define one connection opening OP-C. The connection opening OP-C may be spaced apart from the emission opening OP-E and defined in the pixel defining layer PDL. The first opening portion OP1 and the second opening portion OP2 will be described later.

In the present embodiment, the connection line CN may be connected to the second electrode EL2 through the connection opening OP-C. That is, the connection opening OP-C may expose the emission connection part CE of the connection line CN that will be described later. The connection opening OP-C may overlap the emission connection part CE. Furthermore, the connection opening OP-C may overlap the tip part TP. The connection opening OP-C may be provided in plurality, and the number of the connection openings OP-C may correspond to the number of the emission openings OP-E.

The light-emitting element LD may include a first electrode EL1, an intermediate layer IML, and a second electrode EL2. The first electrode EL1 may be a transflective, transmissive or reflective electrode. According to an embodiment of the inventive concept, the first electrode EL1 may include a reflective layer formed of silver (Ag), magnesium (Mg), aluminum (Al), platinum (Pt), palladium (Pd), gold (Au), nickel (Ni), neodymium (Nd), iridium (Ir), chromium (Cr) or a compound thereof, and a transparent or semitransparent electrode layer formed on the reflective layer. The transparent or semitransparent electrode layer may include at least one selected from the group consisting of indium tin oxide (ITO), indium zinc oxide (IZO), indium gallium zinc oxide (IGZO), zinc oxide (ZnO), indium oxide (In2O3), and aluminum doped zinc oxide (AZO). For example, the first electrode EL1 may include a laminate structure of ITO/Ag/ITO.

In the present embodiment, the first electrode EL1 may be the anode of the light-emitting element LD. That is, the first electrode EL1 may be connected to the first power supply line VDL (see FIG. 2A), and may be applied with the first power supply voltage VDD (see FIG. 2A). The first electrode EL1 may be connected to the first power supply line VDL in the display region DA (see FIG. 3A) or may be connected to the first power supply line VDL in the peripheral region NDA (see FIG. 3A). In the latter case, the first power supply line VDL may be arranged in the peripheral region NDA (see FIG. 3A), and the first electrode EL1 may have a shape extending to the peripheral region NDA (see FIG. 3A).

The first electrode EL1 is illustrated as overlapping the emission opening OP-E and not overlapping the separator SPR in the cross-sectional view of FIG. 5, but, as described above with reference to FIG. 4C, the first electrodes EL1 of each light-emitting element may have a mesh or lattice shape in which the first electrodes EL1 are integrated and openings are defined in a partial region. That is, provided that the same first power supply voltage VDD (see FIG. 2A) is applied to the first electrode EL1 of a plurality of light-emitting elements, a shape of the first electrode EL1 may be variously provided, and is not limited to a certain embodiment.

The intermediate layer IML may be arranged between the first electrode EL1 and the second electrode EL2. The intermediate layer IML may include an emission layer EML and a functional layer FNL. The light-emitting element LD may include the intermediate layer IML of various structures, and is not limited to a certain embodiment. For example, the functional layer FNL may be provided as a plurality of layers, or may be provided as two or more layers spaced apart from each other with the emission layer EML therebetween. Alternatively, the functional layer FNL may be omitted in an embodiment.

The emission layer EML may include an organic light-emitting material. Furthermore, the emission layer EML may include an inorganic light-emitting material or may be provided as a mixture layer of an organic light-emitting material and an inorganic light-emitting material. In the present embodiment, the emission layers EML included in adjacent emission parts EP (see FIG. 3A) may include light-emitting materials for displaying different colors. For example, the emission layers EML included in respective emission parts EP (see FIG. 3A) may provide light of one of blue, red, and green. However, an embodiment of the inventive concept is not limited thereto, and the emission layers EML arranged in all of the emission parts EP (see FIG. 3A) may include light-emitting materials for displaying the same color. In this case, the emission layer EML may provide blue light or white light. Although FIG. 5 illustrates the emission layer EML and the functional layer FNL as having different shapes, the emission layer EML and the functional layer FNL may be arranged in the same shape in a plan view.

The functional layer FNL may be arranged between the first electrode EL1 and the second electrode EL2. In detail, the functional layer FNL may be arranged between the first electrode EL1 and the emission layer EML or between the second electrode EL2 and the emission layer EML. Alternatively, the functional layer FNL may be arranged between the first electrode EL1 and the emission layer EML and between the second electrode EL2 and the emission layer EML. In the present embodiment, the emission layer EML is illustrated as being inserted into the functional layer FNL. However, this is merely an example, and the functional layer FNL may include a layer arranged between the emission layer EML and the first electrode EL1 or a layer arranged between the emission layer EML and the second electrode EL2, or may be provided in plurality for each of the arranged layers, and is not limited to a certain embodiment.

The functional layer FNL may control movement of charge between the first electrode EL1 and the second electrode EL2. The functional layer FNL may include a hole injection/transport material or an electron injection/transport material. The functional layer FNL may include at least one of an electron blocking layer, a hole transport layer, a hole injection layer, a hole blocking layer, an electron transport layer, an electron injection layer, or a charge generation layer.

The second electrode EL2 may be arranged on the intermediate layer IML. In the present embodiment, the second electrode EL2 may be the cathode of the light emitting element LD. As described above, the second electrode EL2 may be connected to the connection line CN so as to be electrically connected to the pixel driving unit PDC. That is, the second electrode EL2 may be electrically connected to the connection transistor TR through the connection line CN.

As described above, the connection line CN may include the driving connection part CD and the emission connection part CE. The driving connection part CD may be a portion of the connection line CN connected to the pixel driving unit PDC and may be substantially a portion connected to the connection transistor TR. In the present embodiment, the driving connection part CD may penetrate the fifth insulating layer 50 and may be electrically connected to the drain region DR of the semiconductor pattern SP through the drain electrode pattern W2. The emission connection part CE may be a portion of the connection line CN connected to the light-emitting element LD. The emission connection part CE may be a portion, which is defined in a region exposed from the sixth insulating layer 60 and connected to the second electrode EL2. Here, the tip part TP may be defined on the emission connection part CE.

The emission connection part CE of the connection line CN will be described in more detail with reference to FIGS. 5 and 6A. As illustrated in FIGS. 5 and 6A, the connection line CN may be provided as a plurality of layers. In detail, the second pattern layer PTL2 of the connection line CN may have a triple-layer structure, and may include a first layer L1, a second layer L2, and a third layer L3 sequentially laminated in a third direction DR3. The second layer L2 may include a material different from that of the first layer L1. Furthermore, the second layer L2 may include a material different from that of the third layer L3. The second layer L2 may have a relatively thick thickness compared to the first layer L1. Furthermore, the second layer L2 may have a relatively thick thickness compared to the third layer L3. The second layer L2 may include a highly conductive material. In an embodiment, the second layer L2 may include aluminum (Al).

Meanwhile, the first layer L1 may include a material having a lower etch rate than that of the second layer L2. That is, the first layer L1 and the second layer L2 may be composed of materials having high etch selectivity therebetween. In an embodiment, the first layer L1 may include titanium (Ti), and the second layer L2 may include aluminum (Al). In this case, a side surface L1_W of the first layer L1 may be defined on a more outward side than a side surface L2_W of the second layer L2. That is, the emission connection part CE of the connection line CN may have a shape in which the side surface L1_W of the first layer L1 protrudes outwards from the side surface L2_W of the second layer L2. That is, the emission connection part CE of the connection line CN may have a shape in which the side surface L2_W of the second layer L2 is recessed inwards from the side surface L1_W of the first layer L1.

Furthermore, the third layer L3 may include a material having a lower etch rate than that of the second layer L2. That is, the third layer L3 and the second layer L2 may be composed of materials having high etch selectivity therebetween. In an embodiment, the third layer L3 may include titanium (Ti), and the second layer L2 may include aluminum (Al). In this case, a side surface L3_W of the third layer L3 may be defined on a more outward side than the side surface L2_W of the second layer L2. That is, the emission connection part CE of the connection line CN may have a shape in which the side surface L3_W of the third layer L3 protrudes outwards from the side surface L2_W of the second layer L2. That is, the emission connection part CE of the connection line CN may have an undercut shape or overhang structure, and the tip part TP of the emission connection part CE may be defined by a portion of the third layer L3, which protrudes from to the second layer L2.

The second organic layer 60 and the pixel defining layer PDL may expose at least a portion of the tip part TP and at least a portion of the second side surface L2_W. In detail, the first opening portion OP1 that exposes one side of the connection line CN may be defined in the second organic layer 60, and the second opening portion OP2 overlapping the first opening portion OP1 may be defined in the pixel defining layer PDL. A flat area size of the second opening portion OP2 (i.e. the area of the second opening portion OP2 in a plan view) may be larger than that of the first opening portion OP1. However, an embodiment of the inventive concept is not limited thereto, and provided that at least a portion of the tip part TP and at least a portion of the second side surface L2_W can be exposed, the flat area size of the second opening portion OP2 may be equal to or less than that of the first opening portion OP1.

The intermediate layer IML may be arranged on the pixel defining layer PDL. The intermediate layer IML may also be arranged on a portion of the second organic layer 60 exposed by the second opening portion OP2 of the pixel defining layer PDL. Furthermore, the intermediate layer IML may also be arranged on a portion of the connection line CN exposed by the first opening portion OP1 of the second organic layer 60. As illustrated in FIG. 6A, the intermediate layer IML may include one end IN1 arranged along an upper surface of the first organic layer 50 and another end IN2 arranged along an upper surface of the tip part TP of the connection line CN. That is, in a cross-sectional view, the intermediate layer IML may have a shape that is partially disconnected at the tip part TP in a region in which the emission connection part CE is defined. However, in a plan view, the intermediate layer IML may have an integrated shape that is overall connected in a region (see FIG. 5) defined by a closed line by the separator SPR.

The second electrode EL may be arranged on the intermediate layer IML. The second electrode EL2 may also be arranged on a portion of the second organic layer 60 exposed by the second opening portion OP2 of the pixel defining layer PDL. Furthermore, the second electrode EL2 may also be arranged on a portion of the connection line CN exposed by the first opening portion OP1 of the second organic layer 60. As illustrated in FIG. 6A, the second electrode EL2 may include one end EN1 arranged along the upper surface of the first organic layer 50 and another end EN2 arranged along the upper surface of the tip part TP of the connection line CN. That is, in a cross-sectional view, the second electrode EL2 may have a shape that is partially disconnected at the tip part TP in a region in which the emission connection part CE is defined. However, in a plan view, the second electrode EL2 may have an integrated shape that is overall connected in a region (see FIG. 5) defined by a closed curve by the separator.

Meanwhile, the one end EN1 of the second electrode EL2 may be arranged along a side surface of the second layer L2 in contact with the side surface L2_W of the second layer L2. In detail, due to a deposition angle difference between the second electrode EL2 and the intermediate layer IML, the second electrode EL2 may be formed so as to contact the side surface L2_W of the second layer L2 exposed from the intermediate layer IML by the tip part TP. That is, the second electrode EL2 may be connected to the connection line CN without an additional patterning process for the intermediate layer IML, and thus the light-emitting element LD may be electrically connected to the pixel driving unit PDC through the connection line CN.

In the present embodiment, the other end IN2 of the intermediate layer IML and the other end EN2 of the second electrode EL2 are illustrated as covering the side surface L3_W of the third layer L3, but this is merely an example, and at least a portion of the side surface L3_W of the third layer L3 may be exposed from the other end IN2 of the intermediate layer IML or the other end EN2 of the second electrode EL2.

Meanwhile, as described above, the display panel DP may include the separator SPR. The separator SPR may be arranged on the pixel defining layer PDL. In an embodiment, the second electrode EL2 and the intermediate layer IML may be formed by being commonly deposited in a plurality of pixels through an open mask. Here, the second electrode EL2 and the intermediate layer IML may be divided by the separator SPR. As described above, the separator SPR may have a closed line shape for each of emission parts, and thus the second electrode EL2 and the intermediate layer IML may have a divided shape in each of emission parts. That is, the second electrode EL2 and the intermediate layer IML may be electrically independent for each of adjacent pixels.

The separator SPR will be described in more detail with reference to FIGS. 5 and 6B. As illustrated in FIG. 6B, the separator SPR may have an inversely tapered shape. That is, an angle θ (hereinafter taper angle) formed by a side surface SPR_W of the separator SPR and the upper surface of the pixel defining layer PDL may be an obtuse angle. However, this is merely an example, and provided that the separator SPR electrically disconnects the second electrode EL2 for each pixel, the taper angle θ may be variously set. Furthermore, the separator SPR may have the same structure as the tip part TP, and is not limited to a certain embodiment.

In an embodiment, the separator SPR may include an insulative material, particularly an organic insulating layer. The separator SPR may also include an inorganic insulating material and may be configured as a multi-layer of an organic insulating material and an inorganic insulating material, and, according to an embodiment, may include a conductive material. That is, provided that the separator SPR electrically disconnects the second electrode EL2 for each pixel, the type of the material of the separator SPR is not particularly limited.

A dummy layer UP may be arranged on the separator SPR. The dummy layer UP may include a first dummy layer UP1 arranged on the separator SPR and a second dummy layer UP2 arranged on the first dummy layer UP1. The first dummy layer UP1 may be formed through the same process and include the same material as the intermediate layer IML. The second dummy layer UP2 may be formed through the same process and include the same material as the second electrode EL2. That is, the first dummy layer UP1 and the second dummy layer UP2 may be formed at the same time when the intermediate layer IML and the second electrode EL2 are formed. In an embodiment, the display panel DP may not include the dummy layer UP.

As illustrated in FIG. 6B, in an embodiment, the second electrode EL2 may include a first end EN1a, and the second dummy layer UP2 may include a second end EN2a. The first end EN1a may be spaced apart from the separator SPR and arranged on the pixel defining layer PDL, and the second end EN2a may be separated from the first end EN1a and arranged on the side surface SPR_W of the separator SPR. Although FIG. 6B illustrates that the first end EN1a is spaced a certain distance apart from the side surface SPR_W of the separator SPR, an embodiment of the inventive concept is not limited thereto, and the first end EN1a may contact the side surface SPR_W of the separator SPR provided that the first end EN1a is electrically insulated from the second end EN2a. Furthermore, even if the first end EN1a and the second end EN2a are connected to each other without being differentiated from each other, the second electrode EL2 may be considered to be divided by the separator SPR if the second electrode EL2 is electrically disconnected between adjacent pixels when a portion formed along the side surface SPR_W of the separator SPR is thin and thus has high electrical resistance.

According to an embodiment of the inventive concept, even if an additional pattern process is not performed for the second electrode EL2 or the intermediate layer IML, the second electrode EL2 or the intermediate IML may be divided in each pixel by not forming the second electrode EL2 or the intermediate layer IML on the side surface SPR_W of the separator SPR or forming the second electrode EL2 or the intermediate layer IML to a thin thickness. Furthermore, provided that the second electrode EL2 or the intermediate layer IML is electrically disconnected between adjacent pixels, a shape of the separator SPR may be variously changed, and is not limited to a certain embodiment.

Referring back to FIG. 5, the encapsulation layer ECL may be arranged on the light-emitting element layer LDL. The encapsulation layer ECL may cover the light-emitting element LD and the separator SPR. The encapsulation layer ECL may include a first inorganic layer IL1, an organic layer OL, and a second inorganic layer IL2 sequentially laminated. However, an embodiment of the inventive concept is not limited thereto, and the encapsulation layer ECL may further include a plurality of inorganic layers and organic layers. Furthermore, the encapsulation layer ECL may be a glass substrate.

The first and second inorganic layers IL1 and IL2 may protect the light-emitting element LD from moisture and oxygen outside the display panel DP, and the organic layer OL may protect the light-emitting element LD from foreign matter such as residual particles during a forming process of the first inorganic layer IL1. The first and second inorganic layers IL1 and IL2 may include a silicon nitride layer, a silicon oxynitride layer, a silicon oxide layer, a titanium oxide layer, an aluminum oxide layer, or the like. The organic layer OL may include an acrylic organic layer, but the type of the material is not limited to a certain material.

The sensing layer ISL may sense an external input. In the present embodiment, the sensing layer ISL may be formed on the encapsulation layer ECL through a continuous process. Here, the sensing layer ISL may be expressed as being directly arranged on the encapsulation layer ECL. “Being directly arranged” may indicate that another component is not arranged between the sensing layer ISL and the encapsulation layer ECL. That is, an additional adhesive member may not be arranged between the sensing layer ISL and the encapsulation layer ECL. However, this is merely an example, and in the display panel DP according to an embodiment of the inventive concept, the sensing layer ISL may be bonded to the display panel DP through an adhesive member after being separately formed, and is not limited to a certain embodiment.

The sensing layer ISL may include a plurality of conductive layers and a plurality of insulating layers. The plurality of conductive layers may include a first sensing conductive layer MTL1 and a second sensing conductive layer MTL2, and the plurality of insulating layers may include first to third sensing insulating layers 71 to 73. However, this is merely an example, and the number of the conductive layers and insulating layers is not limited to a certain embodiment.

The first to third sensing insulating layers 71 to 73 each may have a single-layer structure, or may have a multi-layer structure laminated along the third direction DR3. The first to third sensing insulating layers 71 to 73 may include an inorganic layer. The inorganic layer may include at least one of aluminum oxide, titanium oxide, silicon oxide, silicon nitride, silicon oxynitride, zirconium oxide, or hafnium oxide. The first to third sensing insulating layers 71 to 73 may include an organic layer The organic layer may include at least one of acrylic resin, methacrylic resin, polyisoprene, vinyl-based resin, epoxy-based resin, urethane-based resin, cellulosic resin, siloxane-based resin, polyimide-based resin, polyamide-based resin, or perylene-based resin.

The first sensing conductive layer MTL1 may be arranged between the first sensing insulating layer 71 and the second sensing insulating layer 72, and the second sensing conductive layer MTL2 may be arranged between the second sensing insulating layer 72 and the third sensing insulating layer 73. A portion of the second sensing conductive layer MTL2 may be connected to the first sensing conductive layer MTL1 through a contact hole CNT formed in the second sensing insulating layer 72. The first sensing conductive layer MTL1 and the second sensing conductive layer MTL2 each may have a single-layer structure, or may have a multi-layer structure laminated along the third direction DR3.

The sensing conductive layer of a single-layer structure may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), or indium zinc tin oxide (IZTO). Alternatively, the transparent conductive layer may include a conductive polymer such as PEDOT, metal nanowire, graphene, or the like.

The sensing conductive layer of a multi-layer structure may include metal layers. The metal layers may have, for example, a triple-layer structure of titanium (Ti)/aluminum (Al)/titanium (Ti). Alternatively, the sensing conductive layer of a multi-layer structure may include at least one metal layer and at least one transparent conductive layer.

The first sensing conductive layer MTL1 and the second sensing conductive layer MTL2 may constitute a sensor for sensing an external input in the sensing layer ISL. The sensor may be driven using a capacitive method, and may be driven using either a mutual capacitive method or a self-capacitive method. However, this is merely an example, and the sensor may be driven using a resistive method, ultrasonic method, or infrared method, and is not limited to a certain embodiment.

The first sensing conductive layer MTL1 and the second sensing conductive layer MTL2 each may include a transparent conductive oxide and may also have a metal mesh shape formed of an opaque conductive material. The first sensing conductive layer MTL1 and the second sensing conductive layer MTL2 may have various materials and shapes provided that visibility of an image displayed by the display panel DP does not deteriorate, and are not limited to a certain embodiment.

In the present embodiment, the above-mentioned emission opening OP-E and connection opening OP-C may be defined in the light-emitting element layer LDL. The emission opening OP-E is formed in the pixel defining layer PDL. The emission opening OP-E may expose at least a portion of the first electrode EL1, and may define an emission region. The connection opening OP-C may be spaced apart from the emission opening OP-E in a plan view. The emission opening OP-E and the connection opening OP-C may overlap, in a plan view, the second electrode EL2 constituting one emission part EP (see FIG. 3A). The connection opening OP-C may include the first opening portion OP1 defined in the second organic layer 60 and the second opening portion OP2 defined in the pixel defining layer PDL. The second opening portion OP2 and the first opening portion OP1 may be connected in a thickness direction so as to define one connection opening OP-C.

In the present embodiment, the first opening portion OP1 exposes at least a portion of the connection line CN. The first opening portion OP1 exposes the emission connection part CE in the connection line CN. The first pattern layer PTL1 in the connection line CN may cover at least a portion of a region, which overlaps the first opening portion OP1, in the first organic layer 50.

The second opening portion OP2 may be formed in a region, which overlaps the first opening portion OP1 in a plan view, in the pixel defining layer PDL. Although the second opening portion OP2 is illustrated as having a larger width than the first opening portion OP1, the second opening portion OP2 may have the same width as the first opening portion OP1 provided that the second opening portion OP2 overlaps the first opening portion OP1 in a plan view. The second electrode EL2 formed on the pixel defining layer PDL may be connected to the emission connection part CE of the connection line CN via the second opening portion OP2 and the first opening portion OP1.

According to an embodiment of the inventive concept, the tip part TP of the connection line CN may be formed after the connection opening OP-C is formed. Accordingly, during an etching process for patterning the connection line CN, the first organic layer 50 exposed through the connection opening OP-C may be exposed to an etching environment and thus may be damaged. Since a portion of the first organic layer 50 exposed to an etching environment is etched, an undercut structure may be formed in the connection line CN, particularly between the second pattern layer PTL2 and the first organic layer 50. The second electrode EL2 may be disconnected due to the undercut structure. Accordingly, even if the second electrode EL2 reaches the emission connection part CE via the connection opening OP-C, disconnection may occur between a portion connected to the emission connection part CE and a portion present in the emission opening OP-C, or high resistance may occur due to a thin thickness. Therefore, an electrical fault may occur.

According to an embodiment of the inventive concept, the connection line CN may further include the first pattern layer PTL1. The first pattern layer PTL1 covers at least a portion of the first organic layer 50 exposed. The first pattern layer PTL1 may protect the first organic layer 50 during an etching process of the second pattern layer PTL2. Therefore, the first organic layer 50 may be prevented from being damaged, and a disconnection fault of the second electrode EL2 that may occur between the first organic layer 50 and the connection line CN may be reduced. As a result, electrical reliability and process reliability of a display panel may be improved.

The first pattern layer PTL1 may include a material different from that of the second pattern layer PTL2. For example, the first pattern layer PTL1 may include a material different from that of an element, which contacts the first pattern layer PTL1, in the second pattern layer PTL2 and that of the first layer L1. A material of the first pattern layer PTL1 may have lower reactivity to an etching liquid (or etching gas) than a material of the second layer L2, the etching liquid being sprayed when performing patterning for forming an undercut shape between the first layer L1 and the second layer L2 of the second pattern layer PTL2.

For example, the first pattern layer PTL1 may include a transparent conductive layer. The transparent conductive layer may include a transparent conductive oxide such as indium tin oxide (ITO), indium zinc oxide (IZO), zinc oxide (ZnO), indium zinc tin oxide (IZTO), indium gallium zinc oxide (IGZO), or indium tin gallium zinc oxide (ITGZO). Alternatively, the transparent conductive layer may include a conductive polymer such as PEDOT, metal nanowire, graphene, or the like.

However, this is merely an example, and provided that the first pattern layer protects the first organic layer during a process of forming an undercut shape in the second pattern layer, the first pattern layer may be formed of various materials, and is not limited to a certain embodiment.

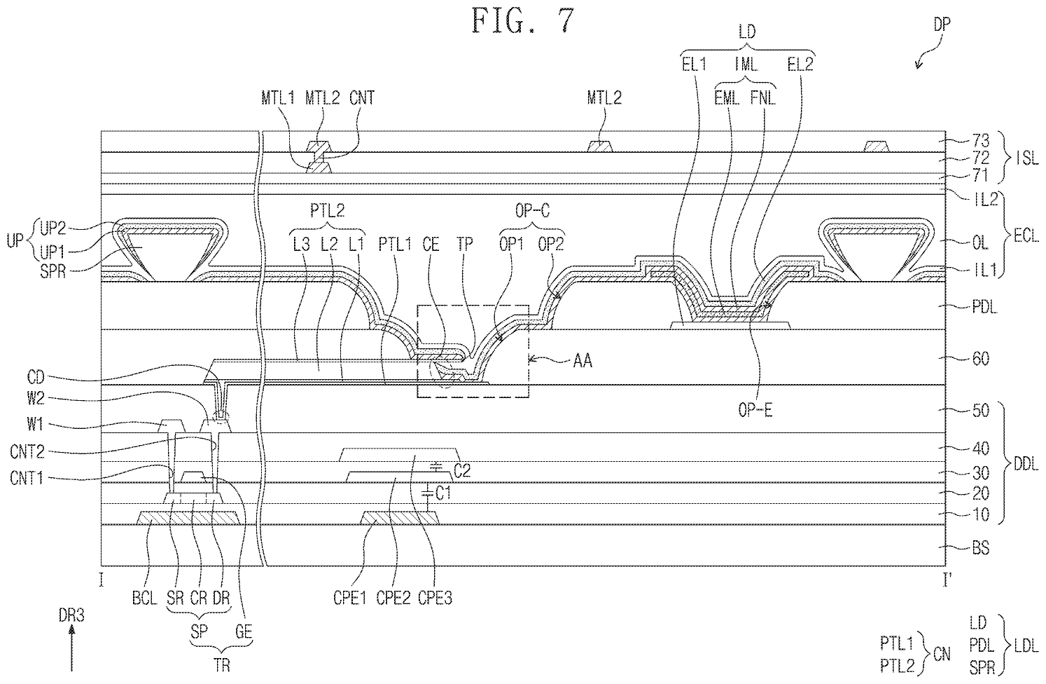

FIG. 7 is a cross-sectional view of a display panel according to an embodiment of the inventive concept. For easy description, FIG. 7 illustrates a cross-section of a region corresponding to FIG. 5. The same reference signs will be used for the same components as described above with reference to FIGS. 1 to 6B, and overlapping descriptions will not be provided.

The first pattern layer PTL1 layer of the connection line CN illustrated in FIG. 7 may further extend along an extension direction of the connection line CN compared to the first pattern layer PTL1 (se FIG. 5) of the connection line CN (see FIG. 5) illustrated in FIG. 5.

According to an embodiment of the inventive concept, the first pattern layer PTL1 may extend along the extension direction of the connection line CN and cover the first organic layer 50 exposed by the first opening portion OP1. An undercut structure may be prevented from being formed between the connection line CN and the first organic layer 50 by preventing the first organic layer 50 being exposed by the first opening portion OP1 during an etching process for patterning the connection line CN.

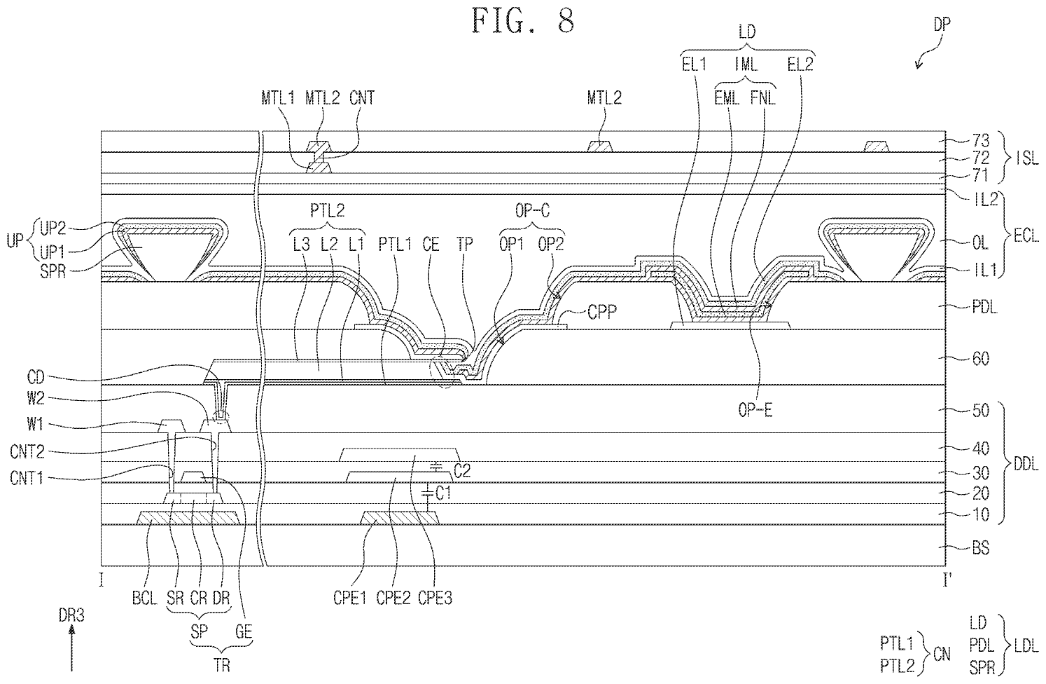

FIG. 8 is a cross-sectional view of a display panel according to an embodiment of the inventive concept. For easy description, FIG. 8 illustrates a cross-section of a region corresponding to FIG. 5. The same reference signs will be used for the same components as described above with reference to FIGS. 1 to 6B, and overlapping descriptions will not be provided.

The display panel DP illustrated in FIG. 8 may further include a capping pattern CPP compared to the display panel DP (see FIG. 5) illustrated in FIG. 5. The capping pattern CPP may be arranged on the second organic layer 60. The capping pattern CPP may overlap the connection opening OP-C, and may also be arranged on a portion of the connection line CN exposed by the first opening portion OP1 of the second organic layer 60. Furthermore, the capping pattern CPP may be arranged on the first organic layer 50. The capping pattern CPP may be arranged overlapping the connection line CN, or the emission connection part CE and the tip part TP.

Furthermore, as illustrated in FIG. 8, in a cross-sectional view, the capping pattern CPP may have a shape that is partially disconnected at the tip part TP in a region in which the emission connection part CE is defined. However, in a plan view, the capping pattern CPP have an integrated shape that is overall connected in a region (see FIG. 5) defined by a closed line by the separator. Meanwhile, one end of the partially disconnected capping pattern CPP may contact a side surface of the second layer L2 of the connection line, and another end of the capping pattern CPP may be arranged on the third layer L3 of the connection line and cover the tip part TP.

The capping pattern CPP may include a conductive material. Accordingly, the second electrode EL2 may be electrically connected to the connection line CN through the capping pattern CPP. That is, the capping pattern CPP contacts the side surface of the second layer L2 of the connection line, and the second electrode EL2 contacts the capping pattern CPP, so that all of the foregoing components may be electrically connected. The capping pattern CPP is arranged on a relatively outer side compared to the second layer L2 of the connection line, and the second electrode EL2 may be electrically connected to the second layer L2 only by connecting to the capping pattern CPP instead of the side surface of the second layer L2, and thus a connection between the connection line CN and the second electrode E2 may be more easily established.

Furthermore, the capping pattern CPP may include a material having relatively low reactivity compared to the second layer L2 of the connection line. For example, the capping pattern CPP may include copper (Cu), silver (Ag), transparent conductive oxide, or the like. Since the side surface of the second layer L2 of the connection line is protected by the capping pattern CPP having relatively low reactivity, oxidation of a material included in the second layer L2 may be prevented. Furthermore, during an etching process for patterning the first electrode EL1, a phenomenon in which silver (Ag) components included in the first electrode EL1 are reduced and remain as particles that cause defect may be prevented.

In an embodiment, the capping pattern CPP may be formed through the same process as the first electrode EL1 and may include the same material as the first electrode EL1. However, this is merely an example, and the capping pattern CPP may be formed through a process different from that of the first electrode EL1 and may include a different material. For example, the capping pattern CPP may be arranged on the first organic layer 50 so as to cover a portion of the first organic layer 50 before an etching process of the second pattern layer PTL2, and thereafter the first organic layer 50 may be protected during an etching process of the second pattern layer PTL2, but an embodiment of the inventive concept is not limited thereto.

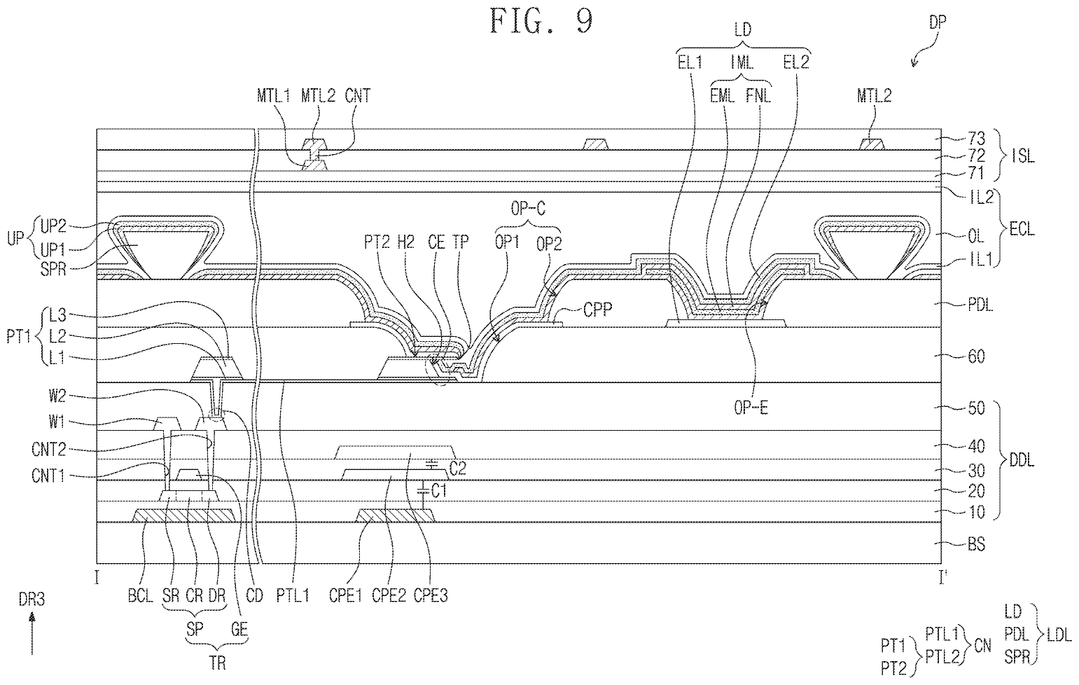

FIG. 9 is a cross-sectional view illustrating a display panel according to an embodiment of the inventive concept. For easy description, FIG. 9 illustrates a cross-section of a region corresponding to FIG. 8. The same reference signs will be used for the same components as described above with reference to FIGS. 1 to 8, and overlapping descriptions will not be provided.

The second pattern layer PTL2 of the connection line CN illustrated in FIG. 9 may include a first pattern PT1 and a second pattern PT2 compared to the second pattern layer PTL2 of the connection line CN (see FIG. 8) illustrated in FIG. 8. The first pattern PT1 and the second pattern PT2 may be arranged spaced apart from each other on the first organic layer 50. That is, the first pattern and the second pattern may be patterns spaced and separated along the extension direction of the connection line.

The first pattern PT1 may be arranged on the driving connection part CD. Therefore, the first pattern PT1 may be connected to the transistor TR. The second pattern PT2 may be arranged on the emission connection part CE. Therefore, the second pattern PT2 may be connected to the second electrode EL2. The tip part PT may be defined on the second pattern PT2 and may overlap the connection opening OP-C.

The first pattern PT1 and the second pattern PT2 each may include a first layer L1, a second layer L2, and a third layer L3 sequentially laminated in a third direction DR3.

The first pattern layer PTL1 may electrically connect the first pattern PT1 and the second pattern PT2. The first pattern layer PTL1 may include a transparent conductive layer, and may include a transparent conductive oxide. Furthermore, the first pattern layer PTL1 may cover the first organic layer 50 so as to prevent damage to the first organic layer 50 when forming a pattern of the connection line CN.

Since damage to the first organic layer 50 may be prevented by using the first pattern layer PTL1 capable of functioning as an extension line for electrically connecting the first pattern PT1 and the second pattern PT2 that are spaced apart from each other, an additional device and additional process are not necessary, thus reducing process time and cost.

The tip part TP may be defined on the second pattern layer PTL2. The tip part TP may be defined on the second pattern PT2 of the second pattern layer PTL2.

As illustrated in the drawings, the display panel DP may include the capping pattern CPP, but an embodiment of the inventive concept is not limited thereto, and the capping pattern CPP may not be provided.

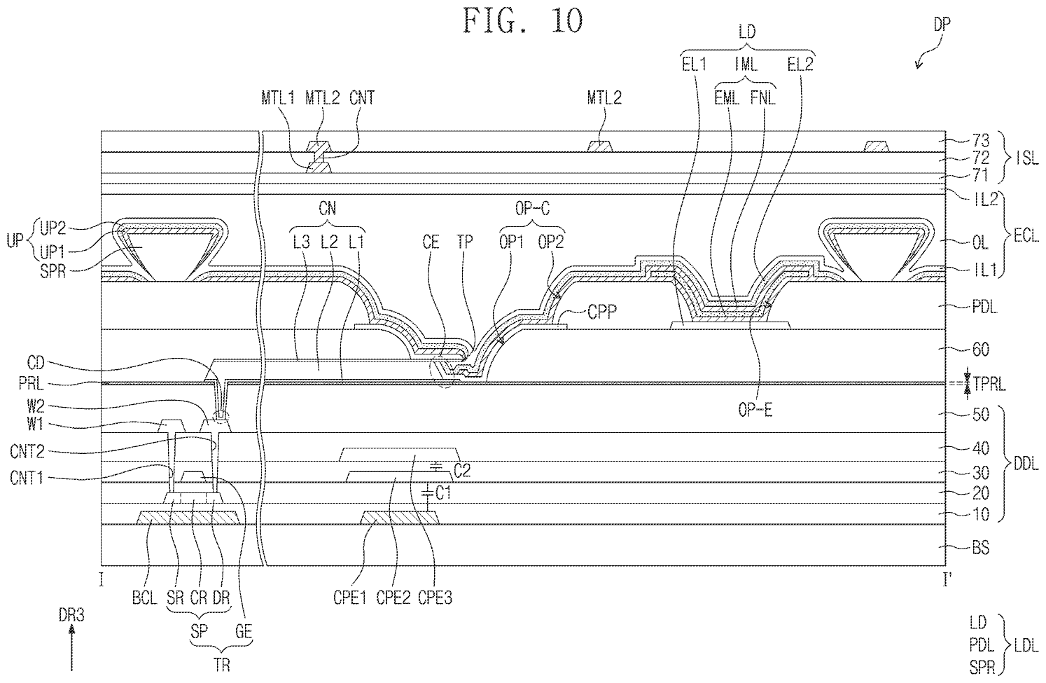

FIG. 10 is a cross-sectional view of a display panel according to an embodiment of the inventive concept. For easy description, FIG. 10 illustrates a cross-section of a region corresponding to FIG. 5. The same reference signs will be used for the same components as described above with reference to FIGS. 1 to 6B and overlapping descriptions will not be provided.

The display panel DP illustrated in FIG. 10 may further include a protective layer PRL arranged between the connection line CN and the first organic layer 50 compared to the display panel DP (see FIG. 5) illustrated in FIG. 5.

The protective layer PRL may cover the first organic layer 50. A thickness TPRL of the protective layer PRL may be about 500 Å to about 5000 Å. By setting the thickness TPRL of the protective layer PRL to at least about 500 Å, the first organic layer 50 may be prevented from being damaged since the protective layer PRL is penetrated when forming a pattern of the connection line CN. The thickness of the display panel DP may be maintained thin by setting the thickness TPRL of the protective layer PRL to at most about 5000 Å, and deterioration of display quality may be prevented.

The protective layer PRL may include silicon (Si). For example, the protective layer PRL may include either silicon oxide (SiOx) or silicon nitride (SiNx), but is not limited thereto and may include both silicon oxide (SiOx) and silicon nitride (SiNx), and is not limited to a certain embodiment.

The tip part TP may be defined on the connection line CN, and the connection line CN may be connected to the transistor TR by penetrating the protective layer PRL and the first organic layer 50.

At least a portion of the protective layer PRL may be exposed by the connection opening OP-C, and the tip part TP may overlap the connection opening OP-C. According to an embodiment of the inventive concept, the protective layer PRL may cover the first organic layer 50 so as to prevent the first organic layer 50 from being exposed by the connection opening OP-C. Accordingly, since the first organic layer 50 may be prevented from being damaged when forming a pattern of the connection line CN, process reliability of the display panel DP may be improved.

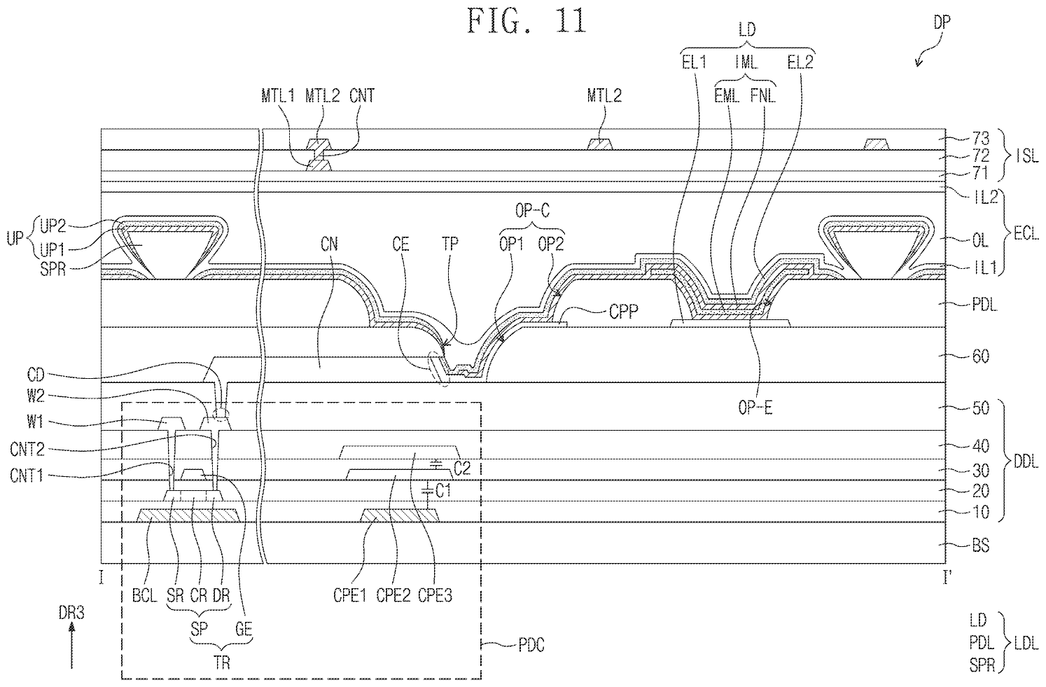

FIG. 11 is a cross-sectional view of a display panel according to an embodiment of the inventive concept. For easy description, FIG. 11 illustrates a cross-section of a region corresponding to FIG. 8. The same reference signs will be used for the same components as described above with reference to FIGS. 1 to 8, and overlapping descriptions will not be provided.

The connection line CN illustrated in FIG. 11 may have a single-layer structure compared to the connection line CN (see FIG. 8) illustrated in FIG. 8.

Here, the connection line CN may have a transparent conductive layer. The transparent conductive layer may include a transparent conductive oxide such as indium tin oxide (ITO), indium zinc oxide (IZO), zinc oxide (ZnO), indium zinc tin oxide (IZTO), indium gallium zinc oxide (IGZO), or indium tin gallium zinc oxide (ITGZO). Alternatively, the transparent conductive layer may include a conductive polymer such as PEDOT, metal nanowire, graphene, or the like.

Here, the connection line CN may not include an undercut-shaped structure such as the tip part TP (see FIG. 5) illustrated in FIG. 5. Accordingly, since an additional etching process for forming a tip part on the connection line CN is skipped after forming the connection opening OP-C, additional damage to the first organic layer 50 may be prevented.

Meanwhile, the display panel DP may include the tip part TP formed between the second organic layer 60 and the connection line CN. In the present embodiment, a side surface, which is arranged on the connection line CN and forms the first opening portion OP1, of the second organic layer 60 may protrude from the connection line CN towards a center of the first opening portion OP1. That is, a side surface of the connection line CN, i.e., the emission connection part CE, may be arranged more inwards than the side surface of the second organic layer 60 forming the first opening portion OP1 and overlap the second organic layer 60 in a plan view, and a step may be defined between the second organic layer 60 and the connection line CN.

The second electrode EL2 may be disconnected by the tip part TP formed between the second organic layer 60 and the connection line CN so as to be connected to the connection line CN. According to an embodiment of the inventive concept, a stable connection may be established between the second electrode EL2 and the transistor TR without damaging the first organic layer 50 by forming the tip part TP between the second organic layer 60 and the connection line CN.

By arranging the connection line CN including a transparent conductive layer on the first organic layer 50, the first organic layer 50 may be prevented from being damaged when forming a pattern of the connection line CN. Furthermore, since the connection line CN includes a transparent conductive oxide, damage to the second organic layer 60 due to etching may also be prevented.

In the present embodiment, the capping pattern CPP that covers at least a portion of the emission connection part CE of the connection line CN may be included. For example, the capping pattern CPP may cover an entirety of the emission connection part CE, but is not limited thereto and may cover a portion of the emission connection part CE.

The capping pattern CPP may prevent damage to the connection line CN that may occur in a subsequent process. For example, the capping pattern CPP may cover the emission connection part CE so as to prevent the connection line CN from being etched in a subsequent process.

The capping pattern CPP may include a material different from that of the connection line CN. For example, the capping pattern CPP may include silver (Ag). However, the capping pattern CPP is not limited thereto may include the same material as the connection line CN, such as indium tin oxide (ITO), and materials included in the capping pattern CPP and the connection line CN are not limited to the above-mentioned embodiments.

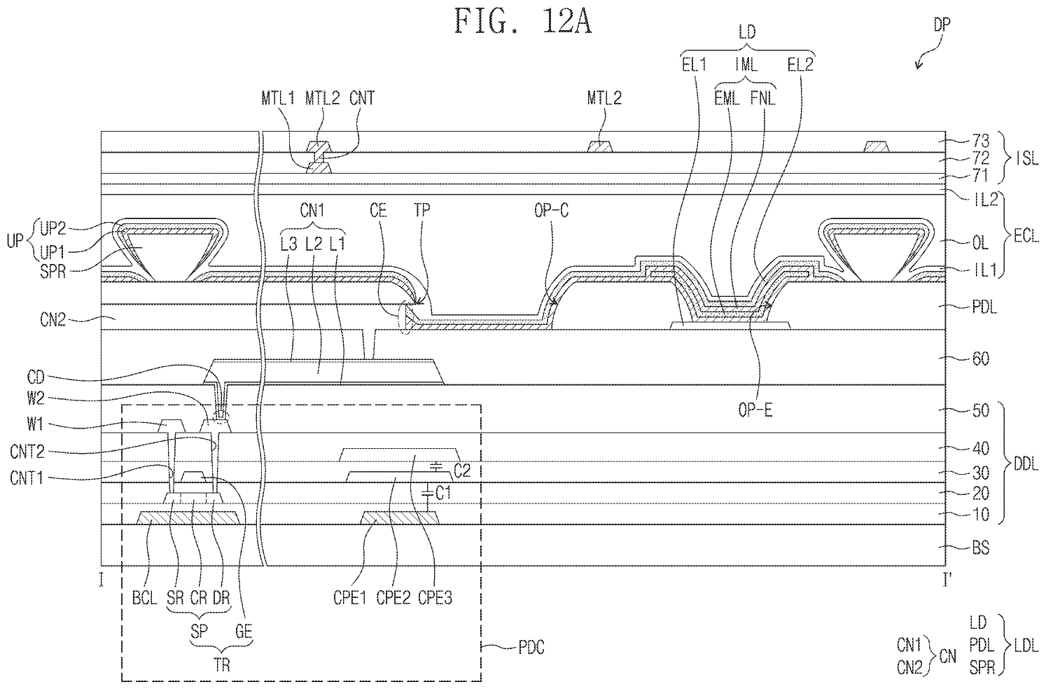

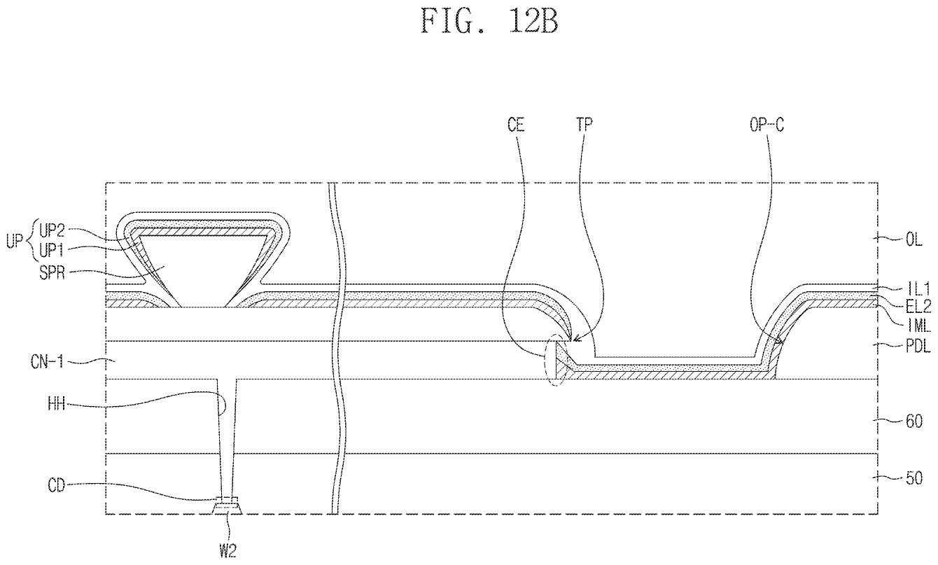

FIG. 12A is a cross-sectional view of a display panel according to an embodiment of the inventive concept, and FIG. 12B is a cross-sectional view of a display panel according to an embodiment of the inventive concept. For easy description, FIG. 12A illustrates a cross-section of a region corresponding to FIG. 8, and FIG. 12B illustrates a cross-section of a region partially corresponding to FIG. 12A. The same reference signs will be used for the same components as described above with reference to FIGS. 1 to 8, and overlapping descriptions will not be provided.

The connection line CN illustrated in FIG. 12A may include a first connection line CN1 and a second connection line CN2 that are arranged on different layers.

The first connection line CN1 may be arranged on the first organic layer 50. The first connection line CN1 may have a structure corresponding to the connection line CN (see FIG. 8) illustrated in FIG. 8. For example, the first connection line CN1 may have a laminate structure including first to third layers L1 to L3.

The second connection line CN2 may be arranged on the second organic layer 60. The pixel defining layer PDL may be arranged on the second connection line CN2. The second connection line CN2 penetrates the second organic layer 60 and is connected to the first connection line CN1.

In the present embodiment, the driving connection part CD may be defined in the first connection line CN1, and the emission connection part CE may be defined in the second connection line CN2. That is, the driving connection part CD and the emission connection part CE may be provided on different layers.

According to an embodiment of the inventive concept, the first connection line CN1 arranged on the first organic layer 50 may not include a tip part. Accordingly, since an additional process for forming a tip part on the connection line CN is skipped after forming the connection opening OP-C, additional damage to the first organic layer 50 and the second organic layer 60 may be prevented.

Meanwhile, the display panel DP may include the tip part TP formed between the pixel defining layer PDL and the second connection line CN2. In the present embodiment, a side surface, which is arranged on the second connection line CN2 and forms the connection opening OP-C, of the pixel defining layer PDL may protrude further than the second connection line CN2 in an extension direction of the second connection line CN2. That is, a side surface of the second connection line CN2, i.e., the emission connection part CE, may be arranged more inwards than the side surface of the pixel defining layer PDL defining the connection opening OP-C and overlap the pixel defining layer PDL in a plan view, and a step may be defined between the pixel defining layer PDL and the second connection line CN2.

According to an embodiment of the inventive concept, the second organic layer 60 may be arranged after arranging the first connection line CN1 on the first organic layer 50, and thereafter the pixel defining layer PDL may be arranged after arranging the second connection line CN2. Thereafter, the emission opening OP-E or the connection opening OP-C may be formed by patterning the pixel defining layer PDL, and thereafter the second connection line CN2 may be etched. Through this process, a step may be defined between the second connection line CN2 and the pixel defining layer PDL by etching the second connection line CN2, and the tip part TP may be defined since the pixel defining layer PDL protrudes from the second connection line CN2. The second electrode EL2 and the intermediate layer IML may be provided for each emission region by being disconnected by the tip part TP.

The connection line CN-1 illustrated in FIG. 12B may be arranged on the second organic layer 60 compared to the connection line CN (see FIG. 12A) illustrated in FIG. 12A. The connection line CN-1 may penetrating the first organic layer 50 and the second organic layer 60 and may be connected to the transistor TR. In detail, the connection line CN-1 may be connected to the transistor TR through a contact hole HH.

A portion of the connection line CN-1 may be arranged on the driving connection part CD. The connection line CN-1 may be connected to the transistor TR through the contact hole HH. Furthermore, a portion of the connection line CN-1 may be arranged on the emission connection part CE. The connection line CN-1 may be connected to the second electrode EL2.

Although not illustrated, the second organic layer 60 may not be provided according to an embodiment. Here, since the pixel defining layer PDL is directly arranged on the first organic layer 50 and a tip part is not formed on the connection line CN-1, a subsequent process that may cause damage to the first organic layer 50 may be skipped. According to an embodiment of the inventive concept, damage to the first organic layer 50 and the second organic layer 60 due to a subsequent process may be prevented since the connection line CN is formed in the same layer as the first electrode EL1, thereby preventing occurrence of an electrical connection fault between the light-emitting element LD and the connection line CN-1.

The display panel according to an embodiment of the inventive concept may prevent damage to an organic layer when patterning a connection line.

The display panel according to an embodiment of the inventive concept may prevent electrode disconnection due to damage to an organic layer.

The display panel according to an embodiment of the inventive concept may prevent deterioration of reliability of display quality.

Although embodiments have been described, it is understood that the present inventive concept should not be limited to these embodiments but various changes and modifications can be made by one ordinary skilled in the art within the spirit and scope of the present invention as hereinafter claimed.

What is claimed is:

1. A display panel comprising:
a light-emitting element including a first electrode, a second electrode arranged on the first electrode, and an intermediate layer arranged between the first electrode and the second electrode;
a transistor electrically connected to the light-emitting element;
a connection line arranged between the light-emitting element and the transistor in a cross-sectional view and including a driving connection part connected to the transistor and an emission connection part connected to the second electrode;
a first organic layer arranged between the transistor and the connection line;
a second organic layer arranged on the first organic layer and between the transistor and the light-emitting element; and
a pixel defining layer arranged between the first electrode and the second electrode and having defined therein a first opening overlapping at least a portion of the first electrode and a second opening spaced apart from the first opening,
wherein the second electrode includes one end connected to the emission connection part and another end spaced apart from the one end in a cross-sectional view.

2. The display panel of claim 1, wherein the connection line includes:
a first pattern layer contacting the first organic layer and including a transparent conductive oxide; and
a second pattern layer arranged on the first pattern layer.

3. The display panel of claim 2, wherein the second pattern layer includes:
a first layer including titanium (Ti);
a second layer arranged on the first layer and including aluminum (Al); and
a third layer arranged on the second layer and including titanium (Ti).

4. The display panel of claim 2, wherein the second pattern layer includes:
a first pattern arranged on the driving connection part; and
a second pattern spaced apart from the first pattern and arranged on the emission connection part.

5. The display panel of claim 4, wherein the second pattern includes a tip part.

6. The display panel of claim 1, further comprising
a protective layer arranged between the first organic layer and the connection line and including silicon,
wherein the connection line penetrates the first organic layer and the protective layer and is connected to the transistor.

7. The display panel of claim 6, wherein the second organic layer is arranged on the protective layer, the second opening overlaps the emission connection part, and at least a portion of the protective layer is exposed by the second opening.

8. The display panel of claim 6, wherein the protective layer has a thickness of about 500 Å to about 5000 Å.

9. The display panel of claim 1, wherein the connection line is arranged between the first organic layer and the second organic layer, and a step is defined between the emission connection part and the second organic layer.

10. The display panel of claim 1, further comprising a capping pattern overlapping the second opening and covering at least a portion of the emission connection part.

11. The display panel of claim 1, wherein the connection line is arranged between the first organic layer and the pixel defining layer, and a step is defined between the emission connection part and the pixel defining layer.

12. The display panel of claim 11, wherein the connection line includes:
a first line arranged on the first organic layer; and
a second line arranged on the second organic layer and having a step defined between the second line and the pixel defining layer.

13. The display panel of claim 1, wherein the light-emitting element is provided in plurality, and the first electrodes of the plurality of light-emitting elements are connected to each other.

14. The display panel of claim 13, wherein the second electrodes of the plurality of light-emitting elements are separated from each other.

15. A display panel comprising:
a light-emitting element including a first electrode, a second electrode arranged on the first electrode, and an intermediate layer arranged between the first electrode and the second electrode;
a transistor electrically connected to the light-emitting element;
a connection line arranged between the light-emitting element and the transistor in a cross-sectional view and including a driving connection part connected to the transistor and an emission connection part connected to the second electrode and having a tip part defined therein; and
a first organic layer arranged between the transistor and the connection line,
wherein the connection line includes a first pattern layer contacting the first organic layer and including a transparent conductive oxide and a second pattern layer arranged on the first pattern layer.

16. The display panel of claim 15, wherein the second pattern layer includes:
a first layer including titanium (Ti);
a second layer arranged on the first layer and including aluminum (Al); and
a third layer arranged on the second layer and including titanium (Ti).

17. The display panel of claim 15, wherein the second pattern layer includes:
a first pattern arranged the driving connection part; and
a second pattern spaced apart from the first pattern, arranged on the emission connection part, and including the tip part.

18. The display panel of claim 15, further comprising:
a pixel defining layer arranged between the first electrode and the second electrode and having defined therein a first opening overlapping at least a portion of the first electrode and a second opening spaced apart from the first opening; and
a capping pattern overlapping the second opening and covering at least a portion of the emission connection part.

19. A display panel comprising:
a light-emitting element including a first electrode, a second electrode arranged on the first electrode, and an intermediate layer arranged between the first electrode and the second electrode;
a transistor electrically connected to the light-emitting element;
a connection line arranged between the light-emitting element and the transistor in a cross-sectional view and including a driving connection part connected to the transistor and an emission connection part connected to the second electrode and having a tip part defined therein;
a first organic layer arranged between the transistor and the connection line; and
a protective layer arranged between the first organic layer and the connection line and including silicon.

20. The display panel of claim 19, further comprising:
a second organic layer arranged on the protective layer and between the transistor and the light-emitting element; and
a pixel defining layer arranged between the first electrode and the second electrode and having defined therein a first opening overlapping at least a portion of the first electrode and a second opening spaced apart from the first opening,
wherein the second opening overlaps the emission connection part, and at least a portion of the protective layer is exposed by the second opening.
